(19) United States
(12) Patent Application Publication
(10) Pub. No.: US 2024/0274207 A1
(43) Pub. Date: Aug. 15, 2024

(54) MEMORY DEVICE

(71) Applicant: Kioxia Corporation, Tokyo (JP)

(72) Inventors: Reika TANAKA, Yokohama (JP); Masumi SAITOH, Yokohama (JP)

(73) Assignee: Kioxia Corporation, Tokyo (JP)

(21) Appl. No.: 18/437,664

(22) Filed: Feb. 9, 2024

(30) Foreign Application Priority Data
Feb. 10, 2023 (JP) 2023-019325

(51) Int. Cl. G11C 16/16; G11C 16/04; G11C 16/08; G11C 16/24

(52) U.S. Cl. CPC G11C 16/16; G11C 16/0433; G11C 16/08; G11C 16/24

(57) ABSTRACT

According to one embodiment, a device includes: first and third transistors coupled to a bit line; first cells coupled to the first transistor; second cells coupled to the third transistor; a first line coupled to a gate of the first transistor; a second line coupled to a gate of the third transistor; word lines coupled to gates of the first and second cells; and a circuit. Each of the first and second cells includes a ferroelectric transistor. In the erase sequence, the circuit applies a first voltage having a positive value to the bit line, applies a second voltage higher than the first voltage to the first and second lines, applies a third voltage higher than the first voltage to non-selected word lines, and applies a fourth voltage lower than the first voltage to a selected word line.

### CROSS-REFERENCE TO RELATED APPLICATIONS

This application is based upon and claims the benefit of priority from Japanese Patent Application No. 2023-019325, filed Feb. 10, 2023, the entire contents of which are incorporated herein by reference.

### FIELD

Embodiments described herein relate generally to a memory device.

### FIELD

Embodiments described herein relate generally to a memory device.

### BACKGROUND

There is proposed a memory device that stores data by utilizing the polarization characteristics of a ferroelectric material.

### BRIEF DESCRIPTION OF THE DRAWINGS

FIG. 1 is a block diagram showing a configuration example of a memory device of the first embodiment.

FIG. 2 is a circuit diagram showing a configuration example of a memory cell array of the memory device of the first embodiment.

FIG. 3 is a cross-sectional view showing a configuration example of the memory cell array of the memory device of the first embodiment.

FIG. 4 is a top view showing a configuration example of a memory cell of the memory device of the first embodiment.

FIG. 5 is a cross-sectional view showing a configuration example of the memory cell of the memory device of the first embodiment.

FIG. 6 is a diagram for illustrating the operating principle of the memory device of the first embodiment.

FIG. 7 is a diagram for illustrating the operating principle of the memory device of the first embodiment.

FIG. 8 is a diagram for illustrating the operating principle of the memory device of the first embodiment.

FIG. 9 is a diagram for illustrating an operation example of the memory device of the first embodiment.

FIG. 10 is a diagram for illustrating an operation example of the memory device of the first embodiment.

FIG. 11 is a diagram for illustrating an erase sequence of the memory device of the first embodiment.

FIG. 12 is a diagram for illustrating the erase sequence of the memory device of the first embodiment.

FIG. 13 is a diagram for illustrating the erase sequence of the memory device of the first embodiment.

FIG. 14 is a diagram for illustrating the erase sequence of the memory device of the first embodiment.

FIG. 15 is a diagram for illustrating a write sequence of the memory device of the first embodiment.

FIG. 16 is a diagram for illustrating the write sequence of the memory device of the first embodiment.

FIG. 17 is a diagram for illustrating the write sequence of the memory device of the first embodiment.

FIG. 18 is a diagram for illustrating the write sequence of the memory device of the first embodiment.

FIG. 19 is a diagram for illustrating an erase sequence of a memory device of the second embodiment.

FIG. 20 is a diagram for illustrating the erase sequence of the memory device of the second embodiment.

FIG. 21 is a diagram for illustrating a write sequence of the memory device of the second embodiment.

FIG. 22 is a diagram for illustrating the write sequence of the memory device of the second embodiment.

FIG. 23 is a diagram for illustrating a modification of the memory device of the embodiment.

FIG. 24 is a diagram for illustrating a modification of the memory device of the embodiment.

### DETAILED DESCRIPTION

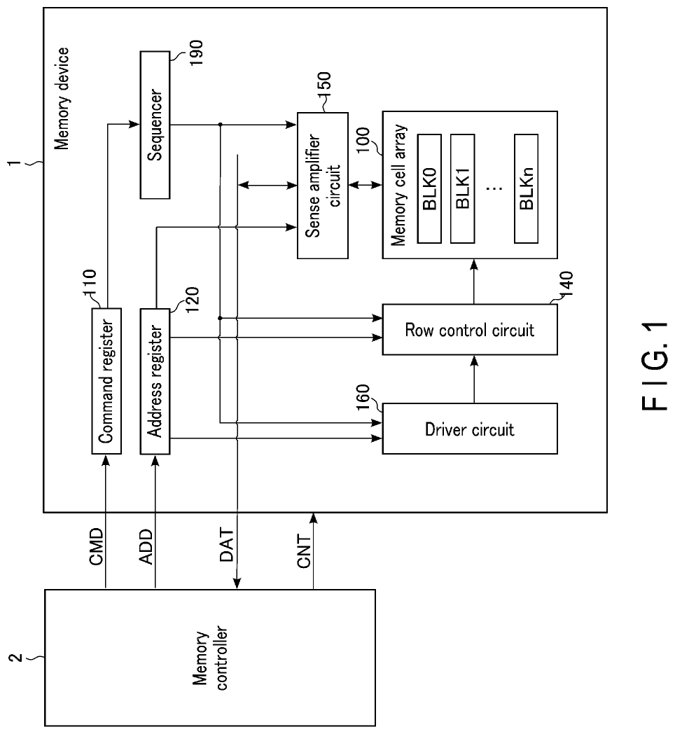

Memory devices of embodiments will be described with reference to FIG. 1 to FIG. 24.

Hereinafter, the embodiments will be described in detail with reference to the accompanying drawings. In the description below, elements having the same functions and configurations will be denoted by the same reference symbols. In the embodiments described below, where constituent elements denoted by reference symbols to which numbers/letters are attached at the end for discrimination (e.g., circuits, interconnects, various voltages and signals) do not have to be discriminated from each other, reference symbols without the numbers/letters at the end will be used.

In general, according to one embodiment, a memory device includes: a first string including a first select transistor, a second select transistor, and a plurality of first memory cells coupled in series between the first select transistor and the second select transistor, the plurality of first memory cells each including a first ferroelectric transistor; a second string including a third select transistor, a fourth select transistor, and a plurality of second memory cells coupled in series between the third select transistor and the fourth select transistor, the plurality of second memory cells each including a second ferroelectric transistor; a first select gate line coupled to a gate of the first select transistor; a second select gate line coupled to a gate of the third select transistor; a plurality of word lines coupled to gates of the plurality of first memory cells and to gates of the plurality of second memory cells; a bit line coupled to one end of the first select transistor and one end of the third select transistor; a source line coupled to one end of the second select transistor and one end of the fourth select transistor; and a circuit that controls an erase sequence, wherein in the erase sequence, the circuit is configured to: apply a first voltage having a positive voltage value to the bit line; apply a second voltage having a positive voltage value higher than the first voltage to each of the first select gate line and the second select gate line; apply a third voltage having a positive voltage value higher than the first voltage to a plurality of first non-selected word lines among the plurality of word lines; and apply a fourth voltage lower than the first voltage to a first selected word line among the plurality of word lines.

### EMBODIMENTS

### (1) First Embodiment

A configuration example of the memory device of the first embodiment will be described with reference to FIG. 1 to FIG. 18.

### (a) Configuration Example

A memory device 1 of the present embodiment will be described with reference to FIG. 1 to FIG. 5.

FIG. 1 is a block diagram illustrating a configuration example of the memory device 1 of the present embodiment.

As shown in FIG. 1, the memory device 1 of the present embodiment is electrically coupled to a memory controller 2.

The memory controller 2 sends a command CMD, an address ADD and various control signals CNT to the memory device 1 of the present embodiment.

The memory device 1 receives the command CMD, address ADD and various control signals CNT. The data DAT is transferred between the memory device 1 and the memory controller 2. In the description set forth below, the data DAT transferred from the memory controller 2 to the memory device 1 during a write sequence will be referred to as write data. The write data DAT is written in the memory device 1. The data DAT transferred from the memory device 1 to the memory controller 2 during a read sequence will be referred to as read data. The read data DAT is read from the memory device 1.

The memory device 1 of the present embodiment includes, for example, a memory cell array 100, a command register 110, an address register 120, a row control circuit 140, a sense amplifier circuit 150, a driver circuit 160 and a sequencer 190.

The memory cell array 100 stores data. The memory cell array 100 is provided with a plurality of bit lines and a plurality of word lines. The memory cell array 100 includes a plurality of blocks BLK0 to BLKn (n is an integer of 1 or more). The block BLK is a set of memory cells. Each memory cell is associated with one bit line and one word line. The configuration of the memory cell array 100 will be described later.

The command register 110 holds a command CMD from the memory controller 2. The command CMD includes, for example, an instruction for causing the sequencer 190 to execute a read sequence, a write sequence, an erase sequence, etc.

The address register 120 holds an address ADD from the memory controller 2. The address ADD includes, for example, a block address, a layer address, a page address, and a column address. The block address, the layer address, the page address, and the column address are used to select a block BLK, a word line, and bit line. In the description below, the block selected based on the block address ADD will be referred to as a selected block. The word line selected based on the address ADD will be referred to a selected word line.

The row control circuit 140 controls the operation related to rows of the memory cell array 100. The row control circuit 140 selects one block BLK in the memory cell array 100, based on the block address in the address register 120. The row control circuit 140 transfers, for example, the voltage applied to the interconnect corresponding to the selected word line to the selected word line in the selected block BLK.

The sense amplifier circuit 150 controls the operation related to the columns of the memory cell array 100. The sense amplifier circuit 150 temporarily holds write data DAT in a write sequence. The sense amplifier circuit 150 applies a voltage to each of the bit lines BL provided in the memory cell array 100 in accordance with the write data DAT from the memory controller 2. In a read sequence, the sense amplifier circuit 150 determines data stored in the memory cell MC, based on the potential of the bit line BL (or whether or not a current is generated). The sense amplifier circuit 150 transfers data based on this determination result to the memory controller 2 as read data.

The driver circuit 160 supplies voltages used in the read sequence, write sequence, erase sequence, etc. to the memory cell array 100. The driver circuit 160 applies a predetermined voltage, for example, to an interconnect corresponding to a word line and an interconnect corresponding to a bit line, based on the address in the address register 120. The driver circuit 160 functions as a read circuit (also referred to as a read driver), a write circuit (also referred to as a write driver), and an erase circuit (also referred to as an erase driver) in each operation sequence performed.

The sequencer 190 controls the overall operation of the memory device 1. For example, the sequencer 190 controls each circuit, based on the command CMD in the command register 110.

For example, communications between the memory device 1 and the memory controller 2 are supported by the NAND interface standard.

The memory device 1 may further include an input/output circuit (not shown), a voltage generation circuit (not shown), etc. The input/output circuit functions as a memory device 1 side interface circuit between the memory device 1 and the memory controller 2.

The voltage generation circuit generates a plurality of voltages for various operations of the memory device 1.

### <Memory Cell Array>

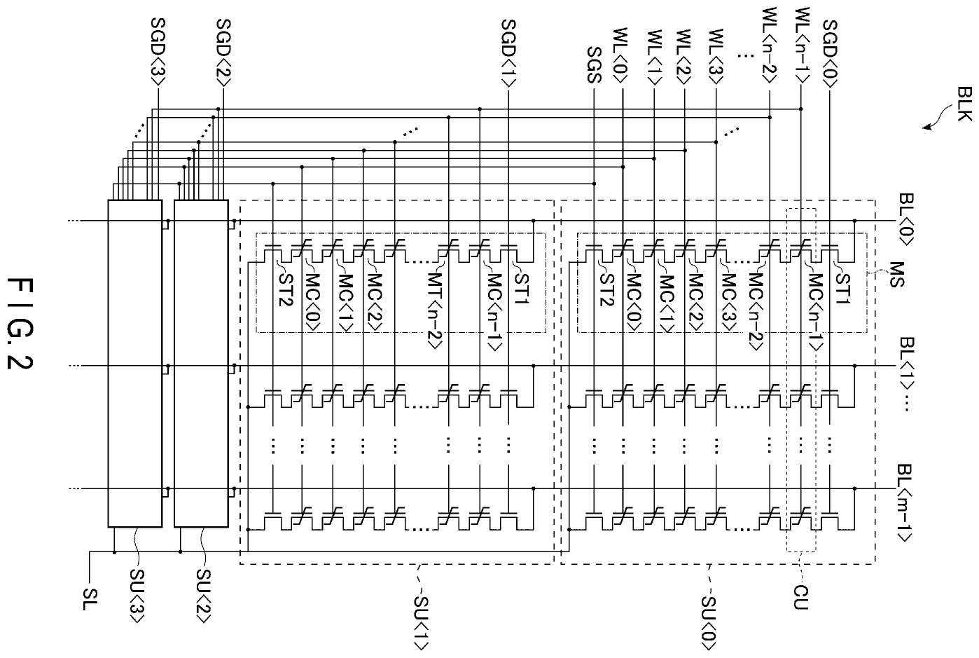

FIG. 2 is a circuit diagram showing a configuration example of a memory cell array of the memory device of the present embodiment.

In FIG. 2, one block BLK of a plurality of blocks BLK included in the memory cell array 100 is extracted and shown.

As shown in FIG. 2, the block BLK includes, for example, four string units SU<0>, SU<1>, SU<2>, and SU<3>. Each string unit SU (SU<0>, SU<1>, SU<2>, SU<3>) includes a plurality of memory cell strings MS. Each of the plurality of memory cell strings MS is coupled to the corresponding one of the plurality of bit lines BL<0>, BL<1>, . . . , BL<m−1>(m is an integer of 1 or more).

Each memory cell string MS includes a plurality of memory cells MC<0>, MC<1>, . . . , MC<n−1>(n is an integer of 1 or more), and select transistors ST1 and ST2. For example, n memory cells MC (MC<0>, MC<1>, MC<2>, MC<3>, . . . , MC<n−2>, MC<n−1>) are provided in each memory cell string MS. The memory cell MC can store one or more bits of data substantially in a non-volatile manner.

Each of the select transistors ST1 and ST2 is used to select a string unit SU during various operations. For example, each select transistor ST1 may include one or more transistors. For example, each select transistor ST2 may include one or more transistors.

In each memory cell string MS, a plurality of memory cells MC are coupled in series between the source of the select transistor ST1 and the drain of the select transistor ST2. The gates of the memory cells MC<0>, MC<1>, MC<2>, MC<3>, . . . , MC<n−2>, MC<n−1> of the same block BLK are coupled to the corresponding ones of a plurality of word lines WL<0>, WL<1>, WL<2>, WL<3>, . . . , WL<n−2>, WL<n−1>.

In each memory cell string MS, one terminal (the drain in this case) of the select transistor ST1 is coupled to the corresponding one of the plurality of bit lines BL<0>, BL<1>, . . . , BL<m−1>. The other terminal (the source in this case) of the select transistor ST1 is coupled to one end of a plurality of memory cells MC coupled in series.

Each of the gates of the select transistor ST1 is coupled to the corresponding one of the plurality of select gate lines SGD. The gates of the select transistors ST1 in the string unit SU0 are coupled to the select gate line SGD0. The gates of the select transistors ST1 in the string unit SU1 are coupled to the select gate line SGD1. The gates of the select transistors ST1 in the string unit SU2 are coupled to the select gate line SGD2. The gates of the select transistors ST1 in the string unit SU3 are coupled to the select gate line SGD3.

One terminal (the drain in this case) of the select transistor ST2 is coupled to the other end of the memory cells MC coupled in series. The other terminal (the source in this case) of the select transistor ST2 is coupled to the source line SL. The sources of the plurality of select transistors ST2 in the same block BLK are commonly coupled to the source line SL.

For example, the gates of the plurality of select transistors ST2 are commonly connected to one select gate line SGS. A plurality of select gate lines SGS may be provided for each string unit SU.

In the circuit configuration of the memory cell array 100 described above, the drains of the select transistors ST1 corresponding to the same column of the plurality of blocks BLK are coupled to the same bit line BL. The source lines SL are, for example, commonly coupled between a plurality of blocks BLK.

The drains of the select transistors ST1 corresponding to the same column of the plurality of string units SU are coupled to the same bit line BL.

A plurality of memory cells MC coupled to the common word line WL in one string unit SU are referred to, for example, as a cell unit CU or a page.

For example, one cell unit CU can store one page of data in the case where each of the memory cells MC stores one bit of data. In the case where each of the memory cells MC stores 2 bits of data, one cell unit CU can store 2 pages of data.

In the present embodiment, the memory cell MC is a ferroelectric transistor (FeFET: ferroelectric field effect transistor). The threshold voltage of the ferroelectric transistor changes depending upon the direction of spontaneous polarization of the ferroelectric layer of the ferroelectric transistor.

The memory device 1 of the present embodiment stores data by associating the data with a change in the threshold voltage of the ferroelectric transistor MC, depending upon the direction of spontaneous polarization.

In the present embodiment, the memory cell MC is also referred to as a ferroelectric transistor MC. In the present embodiment, a memory device using a ferroelectric transistor as a memory cell MC is also referred to as a ferroelectric memory.

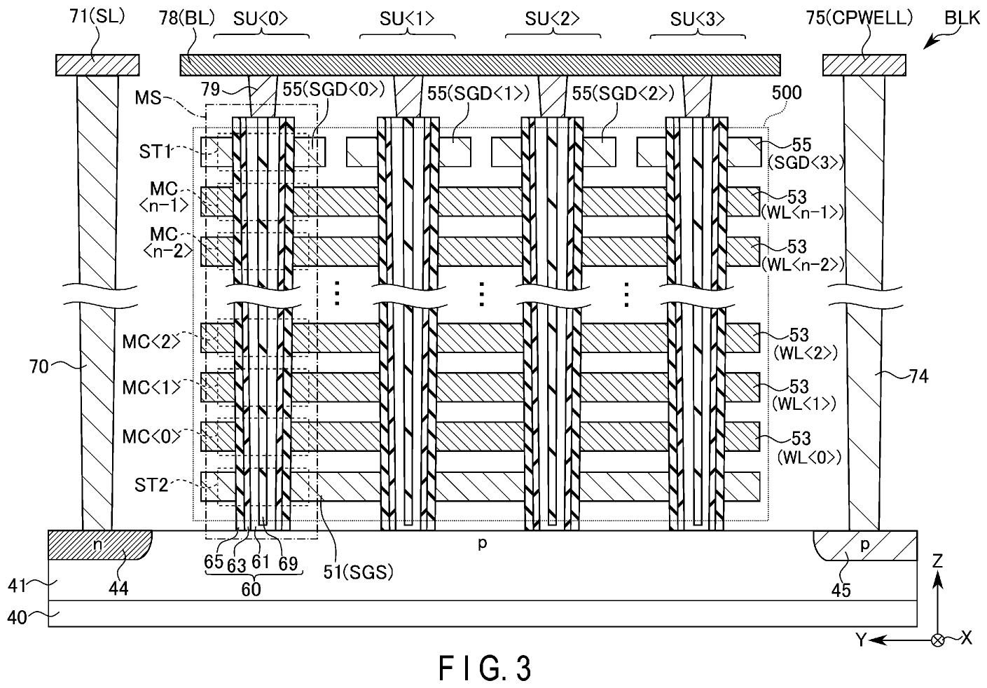

FIG. 3 is a cross-sectional view showing a configuration example of the memory cell array 100 of the memory device 1 of the present embodiment. In FIG. 3, insulating layers (interlayer insulating films) covering the upper surface of the substrate are not shown for clarity of illustration.

As shown in FIG. 3, the plurality of memory cells MC are two-dimensionally arranged on the upper surface (X-Y plane) of the substrate 40. The plurality of memory cells MC are arranged in a direction (Z direction) perpendicular to the upper surface of the substrate 40. As can be seen from this, in the present embodiment, the memory device 1 includes a memory cell array 100 having a three-dimensional configuration.

For example, the substrate 40 is a semiconductor substrate (e.g., a silicon substrate). The substrate 40 includes a semiconductor layer 41.

The semiconductor layer 41 includes a dopant (impurities) according to the conductivity type to be imparted. For example, the semiconductor layer 41 is a p-type semiconductor layer. The semiconductor layer 41 includes a predetermined concentration of p-type dopant (e.g., boron). The semiconductor layer 41 is, for example, a well region provided in the semiconductor substrate 40.

A plurality of semiconductor regions 44 and 45 are provided in the semiconductor layer 41. Each of the semiconductor regions 44 and 45 includes an n-type or p-type dopant (impurities) depending upon the conductivity type to be imparted.

For example, the semiconductor region 44 is an n-type semiconductor region (diffusion layer). The n-type semiconductor region 44 includes an n-type dopant (e.g., phosphorus or arsenic) having a predetermined concentration. The semiconductor region 44 is coupled to an interconnect (e.g., a metal layer) 71 via a contact plug 70. The contact plug 70 is provided on the semiconductor region 44. The contact plug 70 extends in the Z direction. The interconnect 71 is provided above the semiconductor layer 41 in the Z direction. The interconnect 71 functions as a source line SL.

For example, the semiconductor region 45 is a p-type semiconductor region (diffusion layer). The p-type semiconductor region 45 includes a p-type dopant having a predetermined concentration. The semiconductor region 45 is coupled to an interconnect (e.g., a metal layer) 75 via a contact plug 74. The contact plug 74 is provided on the semiconductor region 45. The contact plug 74 extends in the Z direction. The interconnect 75 is provided above the semiconductor layer 41 in the Z direction. The interconnect 75 functions as a well interconnect line CPWELL. The potential of the semiconductor layer 41 can be controlled by applying a voltage to the semiconductor layer 41 via the interconnect 75.

A plurality of conductive layers 51, 53 and 55 are stacked above the semiconductor layer 41 in the Z direction. Insulating layers (not shown) are provided between the conductive layers 51, 53, and 55 that are adjacent in the Z direction.

The conductive layer 51 is arranged above the substrate 40 in the Z direction. The conductive layer 51 has a plate-like structure extending in the X-Y plane. The conductive layer 51 functions as a source-side select gate line SGS. The conductive layer 51 is shared, for example, by a plurality of string units SU (SU<0>, SU<1>, SU<2>, SU<3>).

The plurality of conductive layers 55 are arranged in the Y direction in the region that is above the conductive layer 53 in the Z direction. Each conductive layer 55 extends in the X direction. Each conductive layer 55 functions as a drain-side select gate line SGD (SGD<0>, SGD<1>, SGD<2>, SGD<3>). The conductive layers 55 are separate from each other, for example, for each string unit SU (SU<0>, SU<1>, SU<2>, SU<3>).

The plurality of conductive layers 53 are stacked above the substrate 40 in the Z direction. The plurality of conductive layers 53 are arranged in the Z direction in the space that is between the conductive layer 51 and the conductive layer 55 in the Z direction. Each conductive layer 53 has, for example, a plate-like structure extending in an X-Y plane. Each conductive layer 53 functions as a word line WL. Each conductive layer 53 spans a plurality of string units SU in the block BLK.

A plurality of pillars 60 are provided in a layer stack 500 including the conductive layers 51, 53 and 55 (and the insulating layer (not shown)). Each pillar 60 extends in the Z direction. The pillar 60 penetrates the plurality of conductive layers 51, 53 and 55. The side surface (the plane along the Z direction) of the pillar 60 is opposed to the conductive layers 51, 53 and 55.

The lower end (bottom portion) of the pillar 60 in the Z direction is in contact with the semiconductor layer 41. The upper end (top portion) of the pillar 60 in the Z direction is coupled to an interconnect (e.g., a metal layer) 78 via a contact plug 79. The interconnect 78 extends in the Y direction. The interconnect 78 functions as a bit line BL. For example, a plurality of pillars 60 arranged in the Y direction are commonly coupled to one interconnect (bit line) 78.

The pillar 60 includes a semiconductor layer 61, an insulating layer 63, a ferroelectric layer 65 and a core layer 69. In the present embodiment, the pillar 60 including the ferroelectric layer 65 is referred to as a memory pillar.

The core layer 69 has a columnar structure extending along the Z direction. For example, the upper end of the core layer 69 is arranged in the region between the region where the interconnect 78 of the uppermost layer is provided and the region where the conductive layer 55 is provided. The lower end of the core layer 69 is in contact with the semiconductor layer 61. The core layer 69 includes, for example, an insulator such as silicon dioxide (SiO₂).

The semiconductor layer 61 is provided between the core layer 69 and the insulating layer 63, and between the core layer 69 and the semiconductor layer 41. The lower end of the semiconductor layer 61 is provided between the lower end of the core layer 69 and the upper surface of the semiconductor layer 41. The semiconductor layer 61 has a portion that is in direct contact with the semiconductor layer 41. Thus, the semiconductor layer 61 is electrically coupled to the semiconductor layer 41. For example, the semiconductor layer 61 covers the core layer 69. The semiconductor layer 61 has a cylindrical (or elliptically cylindrical) structure. The semiconductor layer 61 is, for example, a layer including silicon (e.g., a polysilicon layer or an amorphous silicon layer).

The insulating layer 63 is provided between the ferroelectric layer 65 and the semiconductor layer 61. The insulating layer 63 covers the side face (the face extending along the Z direction) of the semiconductor layer 61. The insulating layer 63 is, for example, a layer including silicon oxide.

The ferroelectric layer 65 is provided between the conductive layers 51, 53, 55 and the insulating layer 63. The side face (the face extending along the Z direction) of the ferroelectric layer 65 is opposed to the conductive layers 51, 53 and 55. The ferroelectric layer 65 is, for example, a layer including hafnium oxide. A hafnium oxide layer to which at least one kind of silicon, aluminum, barium, zirconium, gadolinium, lanthanum, strontium and yttrium is added may be used as the ferroelectric layer 65. The ferroelectric layer 65 has a spontaneous polarization property.

A portion including the ferroelectric layer 65 at the intersection between the conductive layer 53 and the memory pillar 60 functions as a memory cell (ferroelectric transistor) MC.

A portion at the intersection between the conductive layer 51 and the memory pillar 60 functions as a select transistor ST2.

A portion at the intersection between the conductive layer 55 and the memory pillar 60 functions as a select transistor ST1.

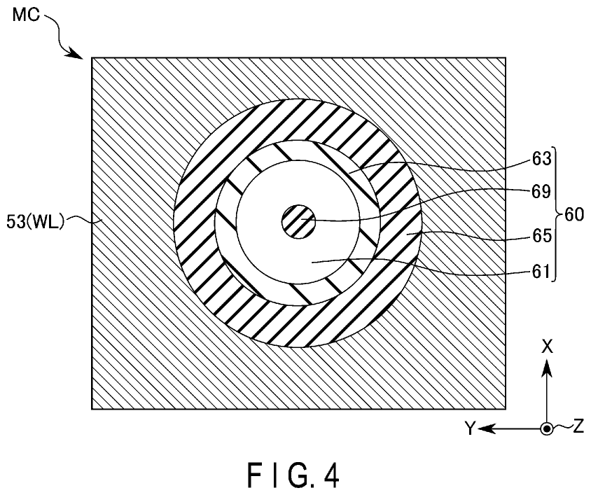

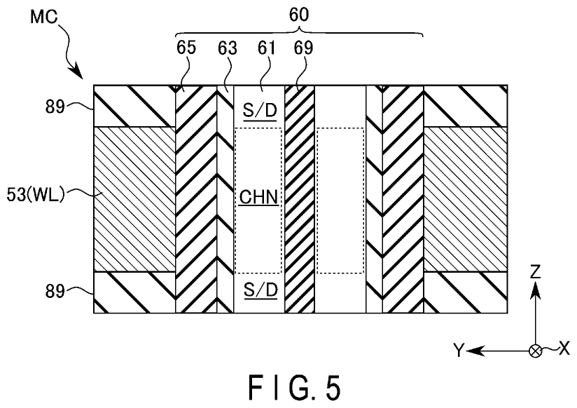

FIG. 4 and FIG. 5 are diagrams for illustrating a configuration example of a memory cell MC of the memory device 1 of the present embodiment. FIG. 4 is a top view for illustrating the planar configuration of the memory cell MC of the present embodiment. FIG. 5 is a cross-sectional view for illustrating a cross-sectional configuration of the memory cell MC of the present embodiment.

As shown in FIG. 4 and FIG. 5, the memory pillar 60 has a cylindrical (or elliptically cylindrical) structure.

The core layer 69 has a cylindrical (or elliptically cylindrical) structure extending in the Z direction.

The semiconductor layer 61 has a cylindrical (or elliptically cylindrical) structure extending in the Z direction.

The insulating layer 63 is provided between the conductive layer 53 and the semiconductor layer 61. The insulating layer 63 has a cylindrical (or elliptically cylindrical) structure. The cylindrical insulating layer 63 covers the side surface (the surface along the Z direction) of the semiconductor layer 61.

The ferroelectric layer 65 is provided between the conductive layer 53 and the insulating layer 63. The ferroelectric layer 65 has a cylindrical (or elliptically cylindrical) structure. The ferroelectric layer 65 having the cylindrical structure covers the side face of the semiconductor layer 61, with the insulating layer 63 interposed.

As described above, the memory cell MC is a ferroelectric transistor in the present embodiment.

The layer stack including the insulating layer 63 and the ferroelectric layer 65 functions as a gate insulating film of the ferroelectric transistor MC. It should be noted that only the insulating layer 63 may be treated as the gate insulating film, in which case the ferroelectric layer 65 is treated as a memory layer. The insulating layer 63 may be a layer stack including a plurality of layers made of different materials, or may be a single-layer film made of one material. The insulating layer 63 will be referred to as an interfacial layer as well.

The conductive layer 53 is a word line WL of the ferroelectric memory 1, and also functions as a gate electrode of the ferroelectric transistor MC. The conductive layer 53 is provided between the insulating layers 89 in the Z direction.

The conductive layer 53 is, for example, a layer stack including a metal layer (e.g., a tungsten layer) and a conductive compound layer (e.g., a titanium nitride layer). In this case, a conductive compound layer (not shown) is provided between a metal layer (not shown) and the insulating layer 89 and between the metal layer and the ferroelectric layer 65.

The source/drain regions and the channel region CHN of the ferroelectric transistor MC are provided inside the semiconductor layer 61. The channel region CHN of the ferroelectric transistor MC faces the conductive layer 53, with the ferroelectric layer 65 and the insulating layer 63 interposed. The two source/drain regions (S/D) of the ferroelectric transistor MC are aligned in the Z direction, with the channel region CHN interposed.

As described above, the ferroelectric transistor MC is a vertical transistor. Therefore, the current path of the ferroelectric transistor MC used as a memory cell is along the Z direction.

The select transistor ST (ST1, ST2) has substantially the same configuration as the ferroelectric transistor MC. It should be noted that the configuration of the select transistors ST may be different from that of the ferroelectric transistor MC. For example, the select transistor ST may have a configuration that does not include a ferroelectric layer (memory layer).

The memory cell array 100 having the configuration shown in FIG. 3 is formed by a known manufacturing method.

### <Operating Principle of Memory Cell>

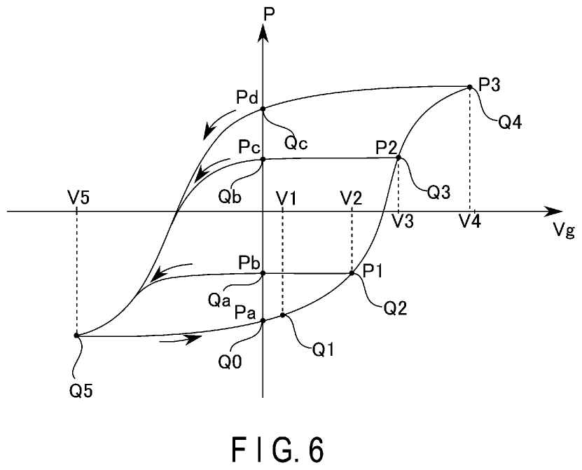

The operating principle of the ferroelectric transistor MC used as a memory cell will be described with reference to FIG. 6 to FIG. 8.

In the memory device 1 of the present embodiment, the ferroelectric transistor MC is used as the memory cell MC by utilization of the polarization characteristics thereof.

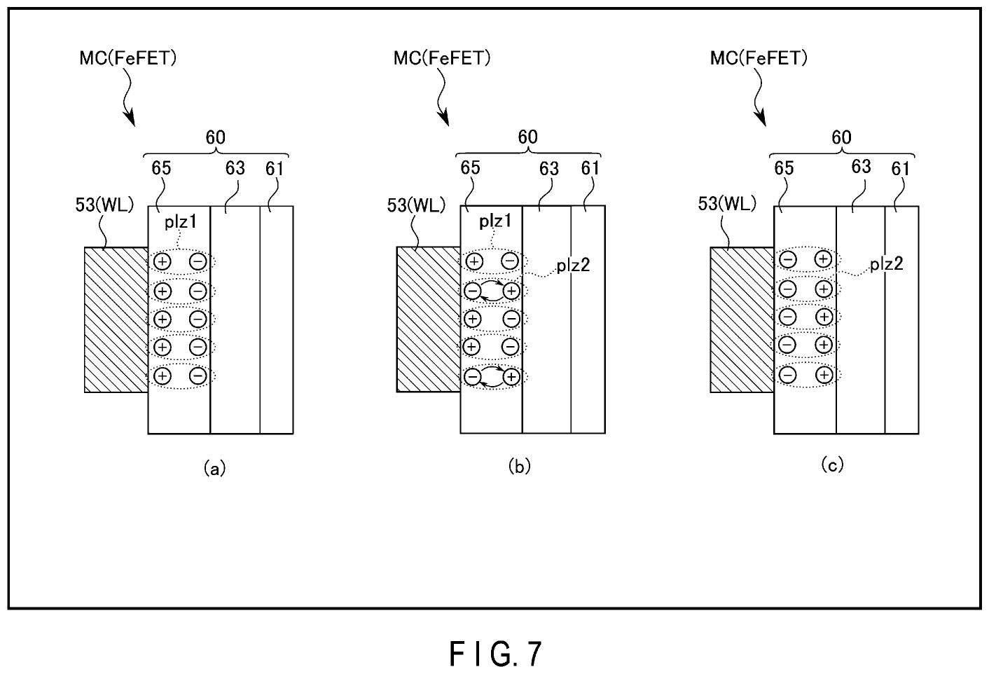

FIG. 6 and FIG. 7 are schematic views for illustrating the characteristics of the ferroelectric transistor MC used as a memory cell. FIG. 6 is a graph showing the polarization characteristics of the ferroelectric transistor MC. The horizontal axis of the graph in FIG. 6 indicates the gate-source voltage Vg of the ferroelectric transistor MC. The vertical axis of the graph in FIG. 6 indicates the spontaneous polarization rate P of the ferroelectric layer 65 of the ferroelectric transistor MC. FIG. 7 is a diagram schematically illustrating the state of the ferroelectric transistor MC exhibited according to the state of spontaneous polarization of the ferroelectric layer 65.

As shown in FIG. 6, the ferroelectric layer 65 has the characteristics shown by a hysteresis curve in the relationship between the voltage Vg and the spontaneous polarization rate P.

When a voltage Vg is applied to the gate (word line) of the ferroelectric transistor MC, an electric field is generated in the ferroelectric layer 65. Due to the influence of the generated electric field, the ions arranged in the crystal lattice of the ferroelectric layer 65 change in position. Thus, polarization is generated in the ferroelectric layer 65.

The spontaneous polarization rate (also referred to as the polarization amount) indicates a degree of spontaneous polarization of the ferroelectric layer 65. The spontaneous polarization rate is an amount of charge due to the spontaneous polarization among an amount of surface charge which is generated in the ferroelectric layer 65 per unit area in the boundary region between the ferroelectric layer 65 and another layer in contact with the ferroelectric layer 65 (i.e., the insulating layer 63 in this case).

For example, when the voltage Vg is 0V and the spontaneous polarization rate of the ferroelectric layer 65 is a negative value Pa (the state indicated by “Q0” in FIG. 6), positive spontaneous polarization charges in spontaneous polarization plz1 are generated on the conductive layer (gate) 53 side, and negative spontaneous polarization charges are generated on the semiconductor layer 61 (channel region) side, as shown in (a) of FIG. 7. In the description below, a state in which positive spontaneous polarization charges are generated on the conductive layer side will be referred to as an up state.

When the voltage Vg applied to the ferroelectric transistor MC is increased from 0V to a certain positive voltage value “V1” in the state where the ferroelectric layer 65 has a negative spontaneous polarization rate (the state indicated by “Q1” in FIG. 6), the spontaneous polarization of the ferroelectric layer 65 is hardly reversed. In this case, the magnitude of the spontaneous polarization rate P of the ferroelectric layer 65 hardly changes.

When the voltage value of the voltage Vg is increased from V1 to a positive voltage value “V2” (state indicated by “Q2” in FIG. 6), the direction of the spontaneous polarization plz2 of the ferroelectric layer 65 is partially reversed with respect to negative spontaneous polarization (hereinafter referred to as a negative spontaneous polarization state as well) plz1, as shown in (b) of FIG. 7. Thus, the spontaneous polarization rate P of the ferroelectric layer 65 sharply increases to a certain value P1.

Once the direction of spontaneous polarization is reversed, the state in which the direction of spontaneous polarization is reversed is maintained even if the voltage value of the voltage Vg is returned from V2 to 0V. Therefore, even if the voltage Vg is lowered from the voltage value V2 to 0V in the state Q2, the spontaneous polarization rate P takes a value Pb larger than the value Pa, as in the state Qa.

When the voltage value of the voltage Vg is increased from V2 to a positive voltage value “V3” (the state indicated by “Q3” in FIG. 6), the reversal of the spontaneous polarization of the ferroelectric layer 65 proceeds, and the spontaneous polarization rate P increases from the negative value P1 to the positive value P2.

As described above, the reversed state of spontaneous polarization is maintained. Therefore, when the voltage value of the voltage Vg is lowered from V3 in the state Q3 to 0V (the state indicated by “Qb” in FIG. 6), the spontaneous polarization rate P takes a value Pc larger than the value Pb.

When the voltage value of the voltage Vg is increased from V3 to a positive voltage value V4 (the state indicated by “Q4” in FIG. 6), the direction of the spontaneous polarization plz2 of the ferroelectric layer 65 is reversed entirely, as shown in (c) of FIG. 7. In this case, the spontaneous polarization rate P increases to a positive value P3, and has a saturation state, for example.

When the voltage value of the voltage Vg is lowered from V4 to 0V, the ferroelectric layer 65 has a spontaneous polarization of positive value Pd even if the voltage Vg is 0V, and therefore maintains a state Qc in which the spontaneous polarization rate is positive.

In spontaneous polarization plz2, negative spontaneous polarization charges are generated on the conductive layer (gate) 53 side, and positive spontaneous polarization charges are generated on the semiconductor layer 61 (channel region) side. In the description below, a state in which negative spontaneous polarization charges are generated on the conductive layer side will be referred to as a down state.

As described above, when the voltage Vg having a positive voltage value is applied to the ferroelectric layer 65 having a negative spontaneous polarization rate, the spontaneous polarization rate of the ferroelectric layer 65 changes from a negative value to a side of a positive value.

When the ferroelectric layer 65 has a positive spontaneous polarization rate, a positive voltage having a magnitude corresponding to the positive spontaneous polarization rate is applied between the gate (conductive layer 53) and the channel region (semiconductor layer 61) of the ferroelectric transistor MC.

As a result, the value of the threshold voltage of the ferroelectric transistor MC of the case where the ferroelectric layer 65 has a positive spontaneous polarization rate decreases, as compared with the value of the threshold voltage of the ferroelectric transistor MC of the case where the ferroelectric layer 65 has a negative spontaneous polarization rate.

When the voltage value of the voltage Vg is decreased from 0V to a negative voltage value “V5” (the state indicated by “Q5” in FIG. 6), the direction of spontaneous polarization of the ferroelectric layer 65 is reversed from the positive polarization direction to the negative polarization direction.

Thus, the spontaneous polarization rate of the ferroelectric layer 65 of the ferroelectric transistor MC changes from a positive value to a negative value. At this time, the spontaneous polarization rate of the ferroelectric layer 65 is saturated with a negative value.

As described above, the spontaneous polarization rate of the ferroelectric layer 65 changes from the positive value to the negative value by application of a voltage Vg having a negative polarity to the ferroelectric transistor MC.

When the voltage value of the voltage Vg is increased from V5 to 0V after the spontaneous polarization rate of the ferroelectric layer 65 changes from the positive value to the negative value, the spontaneous polarization rate of the ferroelectric layer 65 maintains a negative value (e.g., polarization rate Pa).

As described above, the threshold voltage of the ferroelectric transistor MC changes in accordance with a change in the spontaneous polarization rate of the ferroelectric layer 65. The magnitude of the changed threshold voltage is maintained until the application of a voltage having a voltage value that changes the direction of spontaneous polarization of the ferroelectric layer 65.

When the ferroelectric transistor is used as a memory cell MC, a plurality of threshold voltages of the ferroelectric transistor MC, which change according to the spontaneous polarization rate, can be associated with data to be stored.

Therefore, the ferroelectric transistor MC can be applied to the memory device 1 as a memory cell MC that stores data in a non-volatile manner.

### <Relationships Between Threshold Voltage and Data>

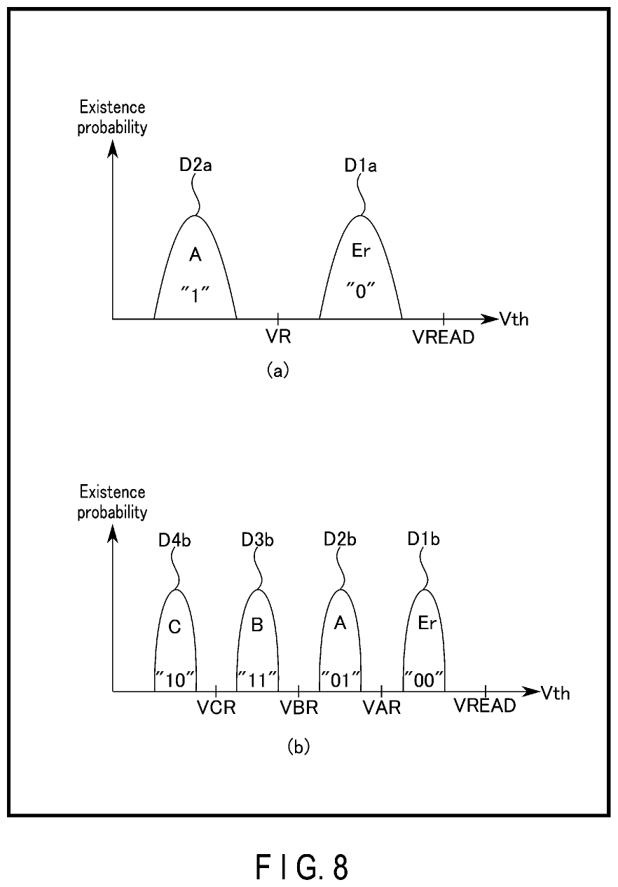

FIG. 8 is a diagram for illustrating the relationships between the threshold voltage of a ferroelectric transistor MC used as a memory cell MC and data. In each of (a) and (b) of FIG. 8, the horizontal axis of the graph corresponds to a threshold voltage Vth of the ferroelectric transistor MC, and the vertical axis of the graph corresponds to an existence probability of the ferroelectric transistor MC.

In (a) of FIG. 8, the graph shows a relationship of “0” data and “1” data to the threshold voltage Vth of the ferroelectric transistor MC when the ferroelectric transistor MC used as a memory cell MC stores 1-bit data. A memory cell (ferroelectric transistor) MC that stores 1-bit data is referred to as an SLC (Single Level Cell).

In the case of (a) of FIG. 8, for example, the state (data holding state) of the ferroelectric transistor MC whose threshold voltage is higher than a certain voltage level VR is called an erased state (or an Er state). The state of the ferroelectric transistor MC whose threshold voltage is lower than the certain voltage level VR is called a programmed state (or an A state).

For example, the erased state of the ferroelectric transistor MC corresponds to a state in which the spontaneous polarization rate of the ferroelectric layer 65 of the ferroelectric transistor MC has a negative value (for example, the state indicated by “Q0” in FIG. 6).

The programmed state of the ferroelectric transistor MC corresponds to a state in which the spontaneous polarization rate of the ferroelectric layer 65 of the ferroelectric transistor MC has a positive value (for example, the state indicated by “Qc” in FIG. 6).

In this case, for example, the threshold voltage distribution D1a of the Er state corresponds to a set of ferroelectric transistors MC including a ferroelectric layer 65 having a spontaneous polarization rate Pa shown in FIG. 6. The threshold voltage distribution D2a of the A state corresponds to a set of ferroelectric transistors MC including a ferroelectric layer 65 having a spontaneous polarization rate Pd shown in FIG. 6.

For example, “0” data is associated with an Er-state ferroelectric transistor MC belonging to the threshold voltage distribution D1a. “1” data is associated with an A-state ferroelectric transistor MC belonging to the threshold voltage distribution D2b.

As described above, when a gate-source voltage Vg having a negative voltage value (e.g., voltage V5) is applied to the memory cell MC, the ferroelectric transistor MC used as a memory cell is set to the erased state. When a gate-source voltage Vg having a positive voltage value (e.g., voltage V4) is applied to the memory cell MC, the ferroelectric transistor MC used as the memory cell is set to the programmed state.

In the description below, a voltage pulse for setting the data holding state of the ferroelectric transistor MC to the erased state will be referred to as an erase pulse. The erase pulse has a negative voltage value.

The voltage pulse for setting the data holding state of the ferroelectric transistor MC to the programmed state is referred to as a write pulse (or program pulse). The write pulse has a positive voltage value.

A voltage value (e.g., the voltage level VR shown in (a) of FIG. 8) that is provided between the adjacent threshold voltage distributions D1a and D2a in order to distinguish the plurality of threshold voltage distributions is called a read level.

When the data stored in the ferroelectric transistor MC is read, a read pulse including one or more read levels VR is applied to the gate of that ferroelectric transistor MC.

When the ferroelectric transistor MC is turned on by application of the read level VR, the ferroelectric transistor MC has a threshold voltage equal to or lower than the read level VR. When the ferroelectric transistor MC is turned off by application of the read level VR, the ferroelectric transistor MC has a threshold voltage higher than the read level VR.

The data stored in the ferroelectric transistor MC is read by detecting a signal determined by the on/off state of the ferroelectric transistor MC.

A voltage level (hereinafter referred to as read pass voltage) VREAD is provided at a voltage level higher than the threshold voltage distribution D1a in the erased state. When the voltage level VREAD is applied to the ferroelectric transistor MC, the ferroelectric transistor MC is turned on without reference to the data it stores.

In (b) of FIG. 8, the graph shows a relationship of “00” data, “01” data, “10” data and “11” data to the threshold voltage of the ferroelectric transistor MC when the memory cell MC stores 2-bit data. A memory cell MC that stores 2-bit data is called an MLC (multi level cell).

In the case of (b) of FIG. 8, the ferroelectric transistor MC for storing 2-bit data has one of an erased state (Er state) and three programmed states (A state, B state, and C state) according to the data it stores.

For example, the threshold voltage distribution D1b of the Er state corresponds to a set of ferroelectric transistors MC including a ferroelectric layer 65 having the spontaneous polarization rate Pa shown in FIG. 6. The threshold voltage distribution D2b of the A state corresponds to a set of ferroelectric transistors MC including the ferroelectric layer 65 having the spontaneous polarization rate Pb shown in FIG. 6. The threshold voltage distribution D3b of the B state corresponds to a set of ferroelectric transistors MC including the ferroelectric layer 65 having the spontaneous polarization rate Pc shown in FIG. 6. The threshold voltage distribution D4b of the C state corresponds to a set of ferroelectric transistors MC including the ferroelectric layer 65 having the spontaneous polarization rate Pd shown in FIG. 6.

For example, “00” data is associated with the ferroelectric transistor MC in the erased state threshold voltage distribution (Er state distribution) D1b. “10” data is associated with the ferroelectric transistor MC of the lowest threshold voltage distribution (C-state distribution) D4b of the four threshold voltage distributions. “01” data is associated with the ferroelectric transistor MC of the threshold voltage distribution (A state distribution) D2b adjacent to the erased state threshold voltage distribution D1b. “11” data is associated with the ferroelectric transistor MC of the threshold voltage distribution (B-state distribution) D3b between the threshold voltage distribution D4b and the threshold voltage distribution D2b.

Read levels VAR, VBR and VCR are provided between two adjacent threshold voltage distributions.

By application of the read level VAR, it is determined whether the threshold voltage of the ferroelectric transistor MC has a value belonging to the erased state (Er state) or a value belonging to the programmed states (the A state, the B state and the C state).

By application of the read level VCR, it is determined whether the threshold voltage of the ferroelectric transistor MC has a value belonging to the C state, or a value belonging to the A state, the B state, or the Er state. By application of the read level VBR, it is determined whether the threshold voltage of the ferroelectric transistor MC has a value belonging to the A state or the Er state, or a value belonging to the B state or the C state.

For example, by application of the read levels VAR and VCR, the lower bit data of the 2-bit data is read. For example, by application of the read level VBR, the upper bit data of the 2-bit data is read.

In this manner, the ferroelectric transistor can be applied to a memory device 1 as a memory cell MC. Thus, a ferroelectric memory is provided.

### (b) Operation Example

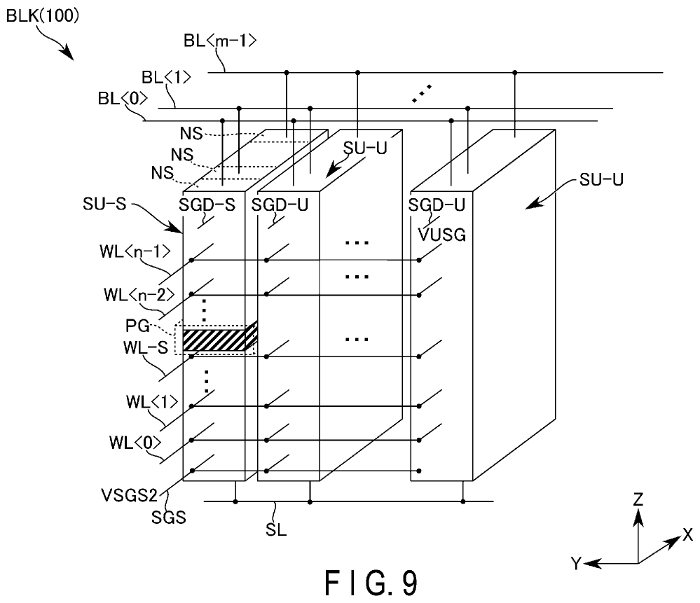

An operation example of the memory device (ferroelectric memory) 1 of the present embodiment will be described with reference to FIG. 9 to FIG. 12.

In the description below, a memory cell (ferroelectric transistor) MC to be operated will be referred to as a selected cell. A memory cell string including the selected cell (a memory cell string to be operated) will be referred to as a selected string. A string unit including the selected string (a string unit to be operated) will be referred to as a selected string unit. A block including the selected string unit (a block to be operated) will be referred to as a selected block. A layer including the selected cell is called a selected layer.

Memory cells other than the selected cell will be referred to as non-selected cells. Memory cell strings other than the selected string will be referred to as non-selected strings. String units other than the selected string unit will be referred to as non-selected string units. Blocks other than the selected block will be referred to as non-selected blocks.

In the description of the present embodiment, various operation sequences that are performed for a memory cell (SLC) storing 1-bit data will be described for the simplicity of description.

(b-1) Selection Area of Each Sequence

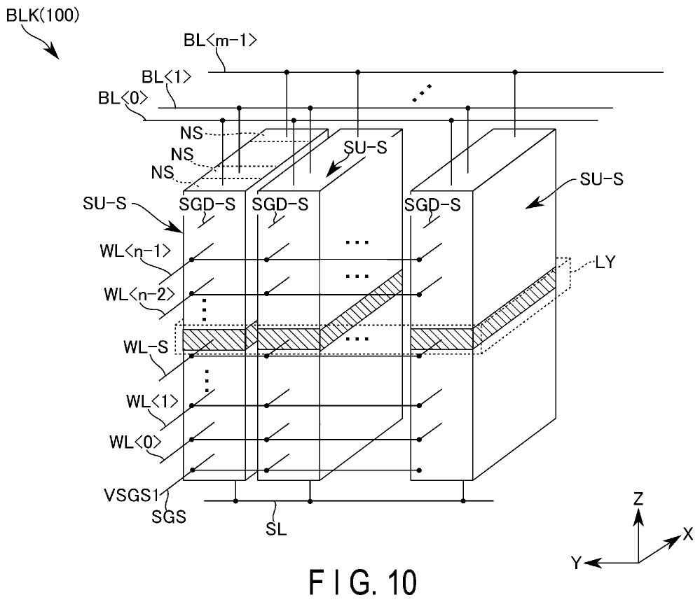

The selection area that is used for each sequence in the memory device 1 of the present embodiment will be described with reference to FIG. 9 and FIG. 10.

FIG. 9 is a schematic diagram illustrating a selection area that is used in the write sequence of the memory device 1 of the present embodiment.

As shown in FIG. 9, in the present embodiment, a page PG is used as a selection area for the write sequence.

The page PG is a set of memory cells MC-S that are included among the memory cells MC coupled to one word line WL-S of the selected block BLK and that belong to one string unit SU.

In the write sequence, one block (selected block) BLK that corresponds to the address is selected from among the plurality of blocks BLK.

In the selected block BLK, one select gate line SGD-S included among the plurality of select gate lines SGD is selected based on an address ADD. The remaining select gate lines SGD-U of the plurality of select gate lines SGD are not selected. Thus, one string unit SU-S is set to a selected state, and the remaining string units SU-U are set to a non-selected state. The string unit SU-S is activated. The string units SU-U are not activated.

One word line (selected word line) WL-S is selected based on the address ADD from among the plurality of word lines WL.

Thus, a plurality of memory cells MC that are coupled to the selected word line WL-S in the selected string unit SU-S are selected as targets of the write sequence in units of pages PG.

In this manner, the write sequence of the memory device 1 of the present embodiment is executed in units of a page PG.

In the read sequence of the memory device 1 of the present embodiment, a page PG is used as the selection area of the read sequence, as in the write sequence.

FIG. 10 is a schematic diagram illustrating selection areas used in the erase sequence of the memory device of the present embodiment.

As shown in FIG. 10, in the present embodiment, a layer LY is used as a selection area for the erase sequence.

The layer LY is a set of memory cells that belong to all string units SU of the selected block BLK and that are coupled to one word line WL-S.

The layer LY is an area smaller than a block BLK and larger than a page PG. For example, the layer LY is an area smaller than a subblock (a control unit including one or more string units).

In the erase sequence, all of the plurality of select gate lines SGD-S are selected in the selected block BLK, based on an address ADD. Thus, all string units SU-S in the selected block BLK are set to the selected state.

One word line (selected word line) WL-S is selected from among the plurality of word lines WL, based on the address ADD.

Thus, a plurality of memory cells (all memory cells) MC coupled to the selected word line WL-S of all string units SU-S are selected as targets of the erase sequence in units of layers LY.

In this manner, the erase sequence of the memory device 1 of the present embodiment is executed in units of a layer LY.

As can be seen from the above, in the memory device 1 of the present embodiment, the selection area for the erase sequence (the number of selected memory cells) is different from the selection area for the write sequence.

(b-2) Erase Sequence

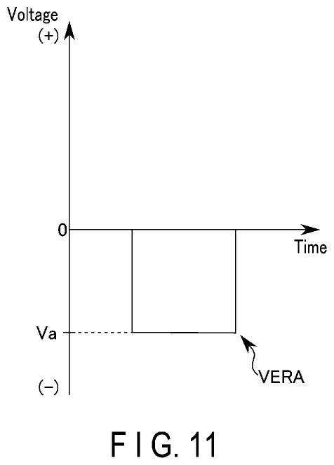

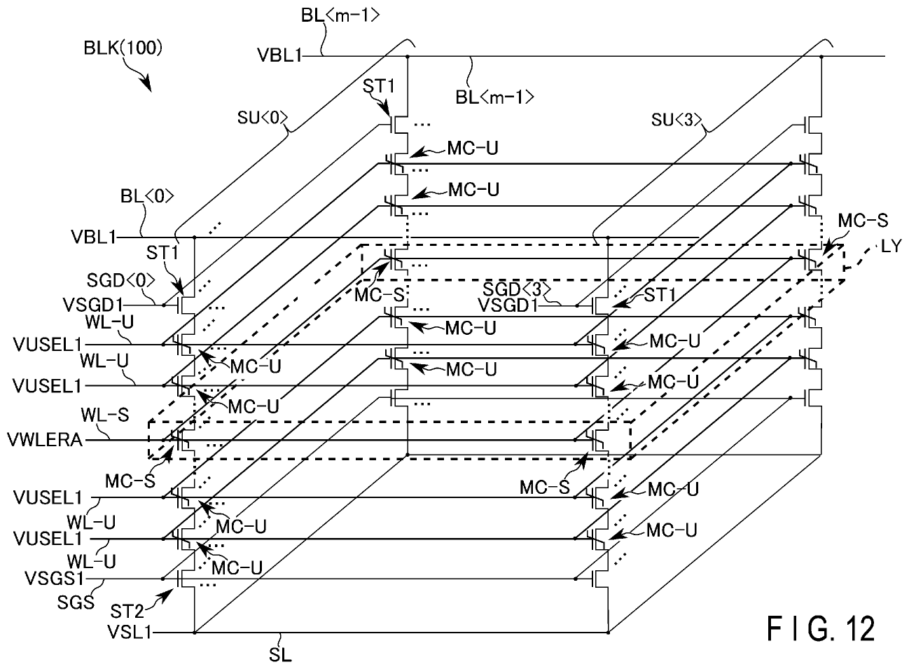

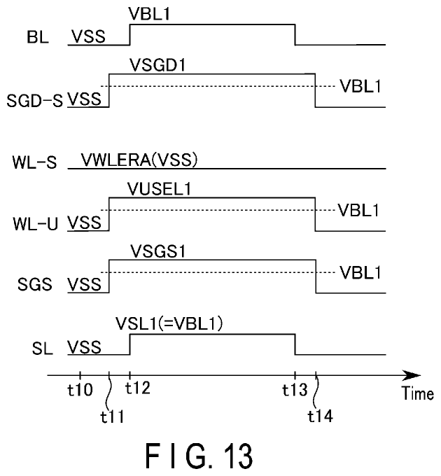

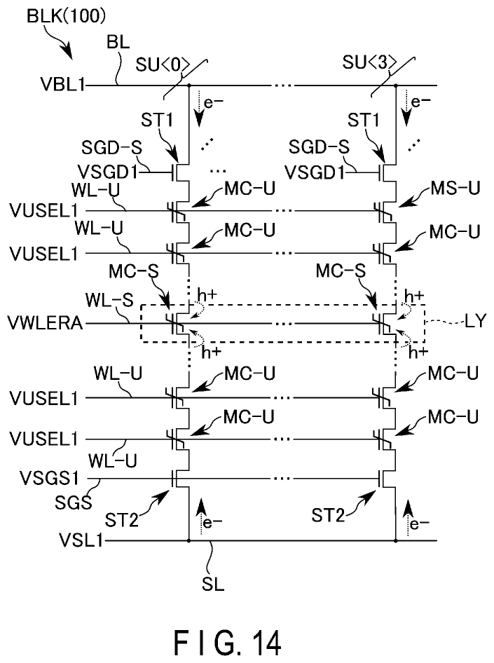

The erase sequence of the memory device 1 of the present embodiment will be described with reference to FIG. 11, FIG. 12, FIG. 13 and FIG. 14.

FIG. 11 is a waveform diagram showing an erase pulse (erase voltage) used in the erase sequence of the memory device 1 of the present embodiment. In FIG. 11, the horizontal axis of the graph corresponds to time, and the vertical axis of the graph corresponds to a voltage value.

As shown in FIG. 11, the erase pulse VERA is a negative polarity voltage. For example, the erase pulse VERA has a rectangular pulse waveform. The erase pulse VERA has a negative voltage value Va. The erase pulse VERA has a certain pulse width.

A negative polarity voltage applied to the ferroelectric transistor MC, such as the erase pulse VERA, is a voltage that causes the potential on the channel region (semiconductor layer 61) side of the ferroelectric transistor MC to be higher than a potential on the gate electrode (conductive layer 53) side of the ferroelectric transistor MC. When a negative polarity voltage is applied to the selected cell MC-S coupled to the selected word line WL-S, the driver circuit 160 raises the potential of the memory pillar 60 to be higher than the potential of the selected word line WL-S.

FIG. 12 is a schematic diagram for illustrating the potential state (applied voltage) of each interconnect in the selected block BLK during the erase sequence of the memory device 1 of the present embodiment. FIG. 13 is a timing chart showing an example of a change in the potential of each interconnect of the selected block BLK during the erase sequence of the memory device 1 of the present embodiment. FIG. 14 is a schematic diagram for illustrating an operation example of the erase sequence of the memory device 1 of the present embodiment.

When the erase sequence is executed, the memory controller 2 sends an erase command CMD and an address (selection address) ADD to the memory device 1. At a certain time (e.g., time t10 in FIG. 13), the memory device 1 receives the erase command CMD and the address ADD.

The memory device 1 of the present embodiment executes an erase sequence for an area in the memory cell array 100 indicated by the address ADD, based on the erase command CMD.

During the erase sequence, the block BLK including the memory cell MC whose data is to be erased, the string unit SU, and the word line WL are each set to a selected state.

The memory device 1 of the present embodiment performs an erase operation in the erase sequence in units of one layer LY. In the erase sequence performed in units of one layer, a plurality of string units SU included in one selected block BLK are selected, and one word line WL shared by the plurality of string units SU is selected.

During the erase sequence performed in units of one layer, the driver circuit 160 supplies various voltages to the plurality of interconnects WL, SGS, SGD, BL and SL of the memory cell array 100 under the control of the sequencer 190.

As shown in FIG. 12 to FIG. 14, at time t11, the driver circuit 160 applies voltages VSGD1 and VSGS1 having positive voltage values to the select gate lines SGD and SGS, respectively, in the erase sequence of the memory device 1 of the present embodiment. In the description below, the voltages applied to the select gate lines SGD and SGS will be referred to as select gate line voltages. For example, in the erase sequence of the present embodiment, the select gate line voltages VSGD1 and VSGS1 are approximately +7.5V.

The driver circuit 160 applies a non-selection voltage VUSEL1 having a positive voltage value to the plurality of non-selected word lines WL-U via the row control circuit 140. For example, the non-selection voltage VUSEL1 is approximately +7.5V. It should be that the non-selection voltage VUSEL1 may be applied to the non-selected word lines WL-U at a time different from the time when the select gate line voltages VSGD1 and VSGS1 are applied.

At time t12, the driver circuit 160 applies voltages VBL1 and VSL1 having positive voltage values to the bit line BL and the source line SL via the sense amplifier circuit 150 and the row control circuit 140. In the description below, the voltage applied to the bit line BL will be referred to as a bit line voltage, and the voltage applied to the source line SL will be referred to as a source line voltage. The bit line voltage VBL1 is a positive voltage lower than the select gate line voltages VSGD1 and VSGS1. The source line voltage VSL1 is a positive voltage lower than the select gate line voltages VSGD1 and VSGS1. In the erase sequence of the present embodiment, the bit line voltage VBL1 and the source line voltage VSL1 are, for example, approximately +5V.

It should be noted that the select gate line voltages VSGD1 and VSGS1 may be applied to the select gate lines SGD-S and SGS, respectively, after the bit line voltage VBL1 and the source line voltage VSL1 are applied to the bit line BL and the source line SL, respectively.

In the present embodiment, the potential difference between the select gate line SGD and the bit line BL and the potential difference between the select gate line SGS and the source line SL have a positive voltage value that is higher than or equal to the threshold voltage of the select transistor ST. For example, the voltage applied between the gate and channel region of the select transistor ST (ST1, ST2) is, for example, +2.5V.

In the erase sequence, therefore, each of the select transistors ST1 and ST2 is turned on. The select transistors ST1 and ST2 in the on state supply electrons (e−) into the memory pillar 60.

In the present embodiment, the potential difference between the non-selected word line WL-U and the bit line BL and the potential difference between the non-selected word line WL-U and the source line SL have positive voltage values. A voltage with positive polarity is applied between the gate and channel region of the non-selected cell MC-U. The positive polarity voltage applied to the ferroelectric transistor MC is a voltage that causes the potential on the gate electrode (conductive layer 53) side of the ferroelectric transistor MC to be higher than the potential on the channel region (semiconductor layer 61) side of the ferroelectric transistor MC. For example, the voltage applied between the gate and channel region of the non-selected cell MC-U is, for example, +2.5V. Accordingly, the non-selected cell MC-U is turned on.

Electrons are supplied to the channel region of the non-selected cell MC-U via the select transistors ST1 and ST2 that are in the on state. Thus, a channel attributable to the electrons is formed in the channel region of the non-selected cell MC-U.

The driver circuit 160 supplies the erase pulse VERA of FIG. 11 to the memory cell MC coupled to the selected word line WL-S corresponding to the selected layer LY.

When a negative polarity voltage is applied to the memory cell MC, the driver circuit 160 causes the potential of the memory pillar 60 to be higher than the potential of the word line WL (conductive layer 53).

As described above, voltages VBL1 and VSL1 having positive voltage values are applied to the bit line BL and source line SL, respectively. The driver circuit 160 applies a selection word line voltage VWLERA having a voltage VSS to the selected word line WL-S corresponding to the selected layer LY. For example, the selection word line voltage VWLERA is a ground voltage. In a more specific example, the selection word line voltage VWLERA is 0V.

Thus, the potential of the channel region (memory pillar 60) of the selected cell MC-S becomes higher than the potential of the gate of the selected cell MC-S.

Therefore, an erase pulse VERA of negative polarity is applied to each selected cell MC-S coupled to the selected word line WL-S. For example, the erase pulse VERA has a voltage value that corresponds to the potential difference between the selected word line WL-S and the bit line BL or the potential difference between the selected word line WL-S and the source line SL. For example, the voltage value of the erase pulse VERA is approximately-5V.

The driver circuit 160 controls the pulse width (voltage supply period) of the erase pulse VERA by controlling the supply periods of the bit line voltage VBL1, the source line voltage VSL1, and the selection word line voltage VWLERA.

In the present embodiment, the erase pulse VERA has a voltage value that causes GIDL (gate induced drain leakage) to occur at the channel edge of the selected cell MC-S (i.e., in the region between the channel region and the drain of the memory cell).

As described above, in the erase sequence of the memory device 1 of the present embodiment, a positive polarity voltage is applied between the gate and channel region of the select transistor ST. Therefore, GIDL does not occur at the channel edge of the select transistor ST. The positive potentials of the bit line BL and source line SL are transferred to the vicinity of the selected cell MC-S via the select transistor ST in the on state and the non-selected cell MC-U.

As shown in FIG. 14, in the present embodiment, GIDL occurs at the channel edge of the selected cell MC-S. Holes (h+) generated by GIDL at the channel edge of the selected cell MC have an influence on the erase operation of the selected cell MC-S. Due to the generated holes, a channel attributable to the holes is formed in the channel region of the selected cell MC-S. Thus, the potential of the channel region of the selected cell MC-S increases. For example, the voltage value of the erase pulse VERA is, for example, approximately −5V.

With the erase pulse VERA being supplied, the ferroelectric transistor MC, which is the selected cell MC-S, is set to the erased state.

It should be noted that the selection word line voltage VWLERA may have either a positive voltage value or a negative voltage value as long as it is a voltage that causes GIDL to occur at the channel edge of the selected cell MC-S.

Thereafter, the supply of the erase pulse VERA is stopped.

At time t13, the driver circuit 160 lowers the potentials of the bit line BL and source line SL. The driver circuit 160 applies a voltage VSS of 0V to the bit line BL and the source line SL. The driver circuit 160 applies a voltage VSS of 0V to the selected word line WL-S.

After the supply of the erase pulse VERA is stopped, at time t14, the driver circuit 160 applies a voltage VSS of 0V to the select gate lines SGD-S and SGS. Thus, the select transistors ST1 and ST2 are turned off.

The driver circuit 160 applies a voltage VSS of 0V to the non-selected word line WL-U. Thus, the non-selected cell MC-U is turned off.

It should be noted that after the voltage VSS is applied to the word lines WL-S and WL-U and the select gate lines SGD-S and SGS, the voltage VSS may be applied to the bit line BL and the source line SL.

In the manner described above, the erase sequence is completed in the memory device 1 of the present embodiment.

In the present embodiment, during the erase sequence, the gate voltage of the memory cell MC of the non-selected cell MC-U is higher than the potential of the channel region (memory pillar). During the erase sequence, a voltage with positive polarity is applied to the non-selected cell MC-U. This suppresses the occurrence of erase disturb in the non-selected cell MC-U. It should be noted that the erase disturb is a defect in which the value of the threshold voltage of a non-selected cell is unintentionally shifted to the erased state.

In the erase sequence of the memory device 1 of the present embodiment, erase verify may be performed after the erase pulse VERA is supplied. It should be noted that the erase sequence may be performed for a plurality of layers LY either simultaneously or consecutively.

(b-3) Write Sequence

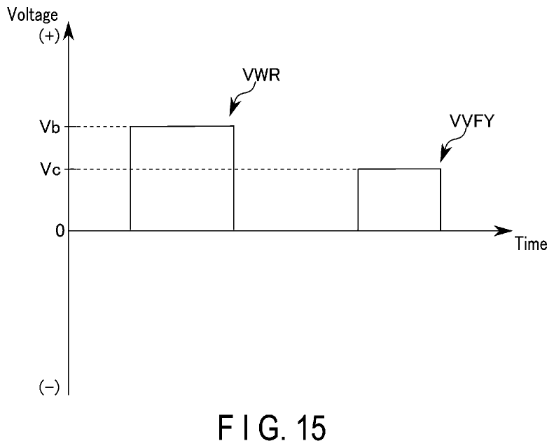

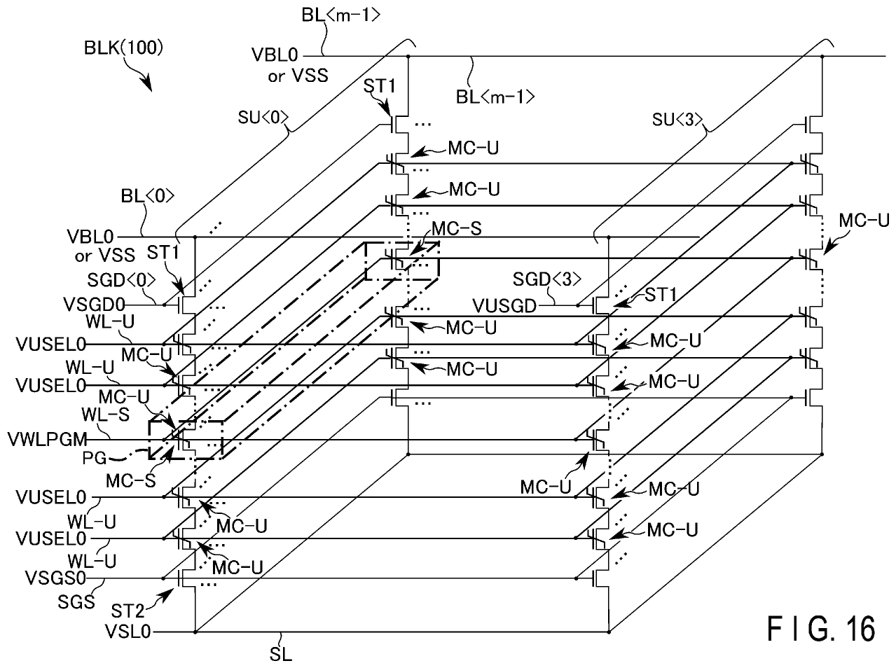

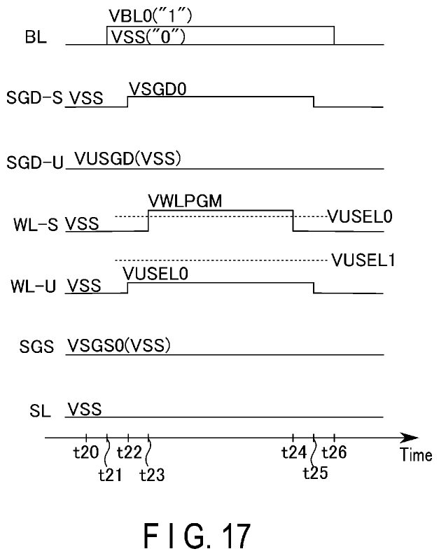

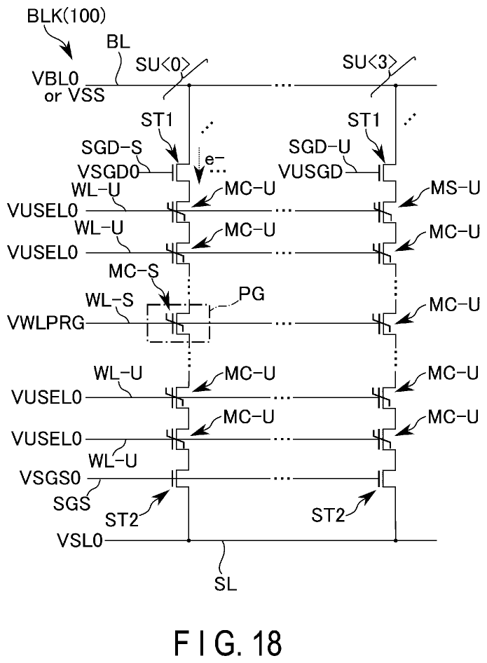

The write sequence of the memory device 1 of the present embodiment will now be described with reference to FIG. 15, FIG. 16, FIG. 17, and FIG. 18.

FIG. 15 is a waveform diagram showing a write pulse (write voltage) used in the write sequence of the memory device 1 of the present embodiment. In FIG. 15, the horizontal axis of the graph corresponds to time, and the vertical axis of the graph corresponds to a voltage value.

As shown in FIG. 15, the write pulse VWR is a positive polarity voltage. For example, the write pulse VWR has a rectangular pulse waveform. The write pulse VWR has a positive voltage value Vb. The write pulse VWR has a certain pulse width.

In the write sequence, the operation of supplying the write pulse VWR to a memory cell (ferroelectric transistor) MC is called a program operation.

A positive polarity voltage applied to the ferroelectric transistor MC, such as the write pulse VWR, is a voltage that causes the potential on the gate electrode (conductive layer 53) side of the ferroelectric transistor MC to be higher than the potential on the channel region (semiconductor layer 61) side of the ferroelectric transistor MC. When the positive polarity voltage is applied to the selected cell MC-S coupled to the selected word line WL-S, the driver circuit 160 raises the potential of the selected word line WL-S to be higher than the potential of the memory pillar 60.

For example, in the write sequence, a program operation based on the supply of the write pulse VWR is first executed, and then a data write verify operation is performed.

In the verify operation, a positive polarity verify pulse VVFY is supplied to the ferroelectric transistor MC. The verify pulse VVFY has a rectangular pulse waveform. The verify pulse VVFY has a positive voltage value Vc. The voltage value Vc is lower than the voltage value Vb. It should be noted that the voltage value Vc is lower than the voltage value at which a change in polarization of the ferroelectric layer of the memory cell MC occurs. The voltage value Vc is set to a voltage value between two adjacent threshold distributions. For example, the voltage value Vc corresponds to the upper limit of the threshold distribution in the programmed state.

By the execution of the verify operation, it is verified whether the threshold voltage of the memory cell MC to which data is to be written has reached the threshold voltage (threshold distribution) corresponding to the data to be written.

When the threshold voltage of the ferroelectric transistor MC has reached the threshold voltage corresponding to the data to be written, the ferroelectric transistor MC to which the verify pulse VVFY is applied is turned on. When the threshold voltage of the ferroelectric transistor MC has not reached the threshold voltage corresponding to the data to be written, the ferroelectric transistor MC to which the verify pulse VVFY is applied is turned off. As a result, it is determined whether or not data write (program operation) has been successfully performed.

FIG. 16 is a schematic diagram for illustrating the potential state (applied voltage) of each interconnect in the write sequence of the memory device 1 of the present embodiment. FIG. 17 is a timing chart showing a change in the potential of each interconnect in the write sequence of the memory device 1 of the present embodiment. FIG. 18 is a diagram for schematically illustrating the state of a selected block BLK during the write sequence of the memory device 1 of the present embodiment.

For example, the write sequence is performed for a memory cell MC in an erased state after the above-described erase sequence is performed.

When the write sequence is executed, the memory controller 2 sends a write command CMD, an address ADD, and write data DAT to the memory device 1. For example, at time t20 shown in FIG. 17, the memory device 1 receives the write command CMD, the address ADD, and the write data DAT.

The memory device 1 of the present embodiment executes a write sequence for the area in the memory cell array 100 indicated by the address ADD, based on the write command CMD.

During the write sequence, the string unit SU and the block BLK, which include the memory cell (selected cell) MC-S to which data is to be written, are set to the selected state.

In the present embodiment, the program operation in the write sequence is executed in units of a page PG. In the program operation performed in units of a page, one string unit SU-S is selected from among the plurality of string units SU of the selected block BLK, and one word line WL-S is selected from among the plurality of word lines WL. In the write sequence, the string units SU-U other than one selected string unit SU-S are not selected.

In the example shown in FIG. 12, a first string unit SU<0> is selected, and a word line WL<i> is selected. Thus, a plurality of memory cells MC (cell unit) belonging to the selected first string unit SU<0> are selected as a programming target from among the plurality of memory cells MC coupled to the selected word line WL-S.

It should be noted that the address of the selected word line WL-S in the write sequence may be the same as or different from the address of the selected word line WL-S in the erase sequence that is executed immediately before the write sequence.

During the write sequence, the driver circuit 160 supplies various voltages to the plurality of interconnects WL, SGD, SGS, BL, and SL of the memory cell array 100 under the control of the sequencer 190.

As shown in FIG. 16 to FIG. 18, at time t21, the driver circuit 160 applies voltages of certain voltage values to the bit line BL and source line SL via the sense amplifier circuit 150 and the row control circuit 140.

A voltage VSS of 0V is applied to the source line SL. It should be noted that in the write sequence, a voltage having a positive voltage value may be applied to the source line SL.

The potential of the bit line BL is determined in accordance with the data written to the selected cell MC-S. A voltage VSS of 0V is applied to a bit line BL coupled to a memory cell (hereinafter referred to as a cell to be programmed) that shifts the magnitude of the threshold voltage of the memory cell MC. A voltage VBL0 having a positive voltage value is applied to a bit line BL coupled to a memory cell (hereinafter referred to as a program-inhibited cell) that does not shift the magnitude of the threshold voltage of the memory cell MC.

At time t22, the driver circuit 160 applies a select gate line voltage VSGD0 having a positive voltage value to a selected select gate line SGD<0> via the row control circuit 140. The voltage VSGD0 is lower than the voltage VSGD1 used in the erase sequence. For example, the voltage value of the voltage VSGD0 is approximately +2.5V.

The select transistor ST1 coupled to the selected select gate line SGD is turned on or off, depending upon the potential difference between the select gate line SGD<0> and the bit line BL.

The driver circuit 160 applies a voltage VUSGD having a certain voltage value to the non-selected select gate lines SGD<1>, . . . , SGD<3> via the row control circuit 140. For example, the voltage VUSGD is, for example, a ground voltage VSS. Thus, the select transistor ST1 coupled to the non-selected select gate line SGD is turned off. Each of the plurality of memory cell strings (non-selected strings) MS of the non-selected string units SU-U is electrically isolated from the bit line BL by the select transistor ST1 in the off state.

The driver circuit 160 applies a voltage VSGS0 having a voltage value of 0V or a positive voltage to the select gate line SGS of the selected block BLK via the row control circuit 140. For example, the select transistor ST2 is turned off. Thus, the plurality of memory cell strings (selected and non-selected strings) MS of the selected block BLK are electrically isolated from the source line SL. The memory pillar 60 of the non-selected string MS is set in the electrically floating state.

The driver circuit 160 applies a voltage VUSEL0 having a positive voltage value (referred to as a non-selection voltage or a write pass voltage) to the plurality of non-selected word lines WL-U via the row control circuit 140. The write pass voltage VUSEL0 is lower than the non-selection voltage VUSEL1 during the erase sequence. For example, the write pass voltage VUSEL0 is approximately +2.5.

At time t23, the driver circuit 160 supplies the write pulse VWR of FIG. 15 to the memory cell MC coupled to the selected word line WL.

As described above, the bit line voltage VBL of 0V or a positive voltage value is applied to the bit line BL in accordance with the data written to the selected cell MC-S. When the voltage VSS is applied to the bit line BL, the voltage VSS of 0V is applied to the memory pillar 60 via the select transistor ST1 in the on state. When the positive voltage VBL0 is applied to the bit line BL, the select transistor ST1 to which the voltage VSGD0 is applied is cut off. Therefore, the memory pillar 60 in which the selected cell MC-S is provided is electrically isolated from the bit line BL by the select transistor ST1 in the cut-off state. The memory pillar 60 in which the program-inhibited selected cell MC-S is provided is set in the electrically floating state.

The driver circuit 160 applies a voltage VWLPGM having a positive voltage value to the selected word line WL-S. The voltage VWLPGM is, for example, approximately +5V.

Thus, a positive polarity write pulse VWR is applied to each of the selected cells MC-S to be programmed. The write pulse VWR has a voltage value Vb determined in accordance with the potential difference between the word line WL-S and the bit line BL selected as a programming target.

For example, the driver circuit 160 controls the pulse width (voltage supply period) of the write pulse VWR by controlling the voltage supply period to the word line WL.

Thus, the threshold voltage of the cell MC-S that is selected to be programmed is shifted to a value corresponding to the threshold voltage in the programmed state.

When a bit line voltage VBL0 has a positive voltage value, the voltage applied between the gate and channel region of the selected cell MC-S, which is a program-inhibited cell, becomes smaller than the pulse VWR by the channel boost in the floating memory pillar 60. In this case, the program-inhibited selected cell MC-S maintains the state prior to the application of the write pulse VWR (e.g., the erased state).

Thereafter, the supply of the write pulse VWR is stopped. At time t24, the driver circuit 160 lowers the voltage of the selected word line WL from the voltage VWLPGM to 0V.

After the supply of the write pulse VWR is stopped, at time t25, the driver circuit 160 applies a voltage of 0V to the plurality of non-selected word lines WL-U. A voltage VSS of 0V is applied to the select gate line SGD-S (and to the select gate line SGS). This turns off the select transistor ST1.

At time t26, the driver circuit 160 applies a voltage of 0V to the bit line BL (and to the source line SL).

In the manner described above, the program operation of the write sequence is completed.

For example, the driver circuit 160 performs a write sequence verify operation after the program operation. The verify operation verifies the magnitude of the threshold voltage of the selected cell MC after the program operation.

As shown in FIG. 15, a voltage (verify pulse) VVFY having positive polarity (a positive voltage value) is supplied to the selected cell MC.

The driver circuit 160 applies a voltage having a positive voltage value to the bit line BL. In addition, the driver circuit 160 applies a voltage having a positive voltage value to the selected select gate lines SGD and SGS. This turns on the select transistors ST1 and ST2.

During the verify operation, the driver circuit 160 applies a voltage (non-selection voltage) VREAD having a positive voltage value to the non-selected word lines WL-U. Accordingly, the non-selected cells MC-U are turned on.

The driver circuit 160 applies a voltage having a positive voltage value to the selected word line WL-S. Thus, a verify pulse VVFY is applied between the gate and channel of the selected cell MC-S.

At the time of application of the verify pulse VVFY, the selected cell MC-S is turned on or off, depending upon whether or not the threshold voltage of the selected cell MC is higher than the voltage value of the verify pulse VVFY. When the selected cell MC-S is turned on, a current (hereinafter referred to as a cell current as well) flows from the bit line BL to the source line SL. When the selected cell MC-S is turned off, no cell current is generated. As a result, it is determined whether or not the selected cell MC-S has a threshold voltage corresponding to the data to be stored, based on whether the selected cell MC-S is turned on or off in response to the application of the verify pulse VVFY.

Thereafter, the supply of the verify pulse VVFY is stopped. The driver circuit 160 applies a voltage of 0V to the plurality of word lines WL.

After the supply of the verify pulse VVFY is stopped, a voltage of 0V is applied to the selected select gate lines SGD and SGS. Thus, the select transistors ST1 and ST2 are turned off. The driver circuit 160 applies a voltage of 0V to the bit line BL and the source line SL.

Based on the result of the verify operation, it is determined whether the write pulse VWR should be applied again. For example, the program operation and the verify operation are repeatedly executed until the threshold voltage of the selected cell MC reaches a value corresponding to the data to be stored. If it is determined by the verify operation that the threshold voltage of the selected cell has reached a value corresponding to the data to be stored, the write sequence is completed.

In the manner described above, the write sequence is completed in the memory device 1 of the present embodiment.

In the present embodiment, the occurrence of erase disturb is suppressed. Therefore, the memory device 1 of the present embodiment can write data to the memory cells that are not affected by erase disturb. As a result, the memory device 1 of the present embodiment can reduce data write errors.

It should be noted that the read sequence of the memory device 1 of the present embodiment is executed by a well-known technique.

For example, in the read sequence, one string unit SU and one word line WL are selected from the selected block BLK. Thus, one page (cell unit) is selected. A positive voltage is applied to the bit line BL. A positive voltage is applied to the selected select gate line SGD and select gate line SGS. A non-selection voltage VREAD is applied to a plurality of non-selected word lines WL. A certain read level (read voltage) is applied to the selected word line WL.

In the read sequence, data in the selected cell is determined depending upon whether the selected cell coupled to the selected word line is turned on or off. When the threshold voltage of the selected cell is higher than the read level, the selected cell is turned off. When the selected cell is turned off, the potential of the bit line BL is maintained. When the threshold voltage of the selected cell is below the read level, the selected cell is turned on. When the selected cell is turned on, a current is generated between the bit line BL and the source line SL due to discharge of the bit line BL, and the potential of the bit line lowers.

Based on the detection of the discharge current of the bit line BL or the change in the potential of the bit line, it is determined whether the data in the selected cell is “0” data or “1” data.

In this manner, the data in the selected cell is read by the read sequence in the memory device 1 of the present embodiment.

### (c) Summary

To improve the operating characteristics of a ferroelectric memory, there may be a case where an erase sequence performed in units of one layer is used for that ferroelectric memory.

In a general ferroelectric memory, erase disturb is likely to occur in an erase sequence performed in units of one layer. For this reason, the general ferroelectric memory that executes an erase sequence in units of one layer may not meet specifications required of data erase.

In the general ferroelectric memory, even if program disturb occurs, specifications required data programming can be met with relative ease. It should be noted that the program disturb is a defect in which the value of the threshold voltage of a non-selected cell is unintentionally shifted to the programmed state side in a write sequence.

In the memory device 1 of the present embodiment, during the erase sequence performed in units of one layer, electrons attributable to GIDL are generated in the vicinity of a selected cell MC-S in the state where the electrons are supplied to the channel region of non-selected cells MC-U via the select transistor ST in the on state.

Thus, in the present embodiment, the selected cell MC-S in the selected layer LY is set to the erased state, and yet erase disturb that may occur in non-selected cells MC-U can be suppressed.

Therefore, the memory device 1 of the present embodiment can reduce errors caused by the erase disturb.

As described above, the memory device 1 of the present embodiment can improve reliability.

### (2) Second Embodiment

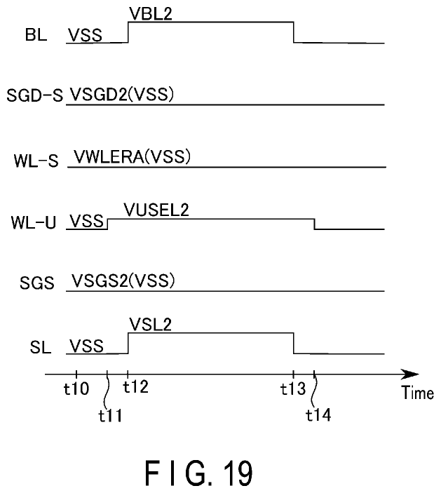

A memory device of the second embodiment will now be described with reference to FIG. 19 to FIG. 22.

In the memory device 1 of the present embodiment, the non-selection voltage that is applied to the non-selected word line WL-U in the write sequence is higher than the non-selection voltage that is applied to the non-selected word line WL-U in the erase sequence. Thus, the influence of the erase disturb that may occur during the erase sequence is canceled by the control of the threshold voltage of the memory cell MC performed during the write sequence.

The memory device 1 of the present embodiment executes an erase sequence and a write sequence in the manner described below.

### <Erase Sequence>

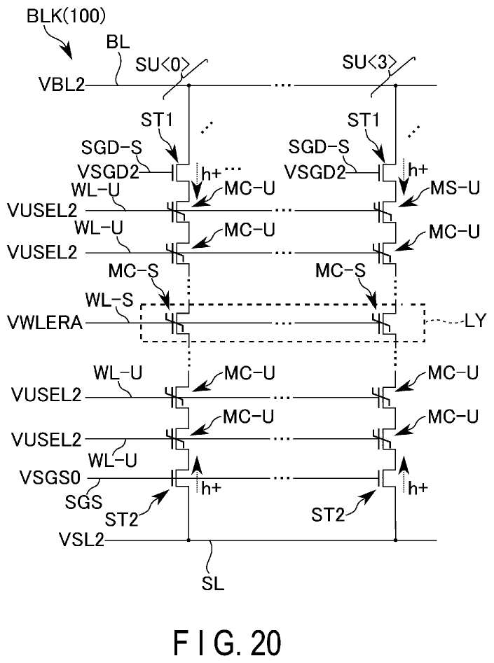

The erase sequence of the memory device 1 of the present embodiment will be described with reference to FIG. 19 and FIG. 20.

FIG. 19 is a timing chart showing a change in the potential of each interconnect of the selected block BLK in the erase sequence of the memory device 1 of the present embodiment. FIG. 20 is a schematic diagram for illustrating the erase sequence of the memory device 1 of the present embodiment.

Similar to the embodiment described above, the memory device 1 of the present embodiment executes an erase sequence in units of layers.

As shown in FIG. 19 and FIG. 20, in the erase sequence, the driver circuit 160 supplies various voltages to the plurality of interconnects WL, SGS, SGD, BL and SL of the memory cell array 100 under the control of the sequencer 190.

At time t11, the driver circuit 160 applies a non-selection voltage VUSEL2 having a positive voltage value to the plurality of non-selected word lines WL-U. For example, the non-selection voltage VUSEL2 is approximately +2.5V. Thus, the memory cell MC-U coupled to the non-selected word line WL-U is set to a non-selected state.

At time t12, the driver circuit 160 applies a bit line voltage VBL2 having a positive voltage value to the plurality of bit lines BL of the selected block BLK. The driver circuit 160 applies a source line voltage VSL2 having a positive voltage value to the source line SL of the selected block BLK. Each of the bit line voltage VBL2 and the source line voltage VSL2 is higher than the non-selection voltage VUSEL2, for example. Each of the bit line voltage VBL2 and the source line voltage VSL2 is, for example, approximately +5V.

The driver circuit 160 applies select gate line voltages VSGD2 and VSGS2 having certain voltage values to the select gate lines SGD and SGS, respectively. For example, the select gate line voltages VSGD2 and VSGS2 are voltages VSS of approximately 0V.

Thus, the potential of the gate of the select transistor ST becomes lower than the potential of the edge of the channel region of the select transistor ST, depending upon the potential difference between the select gate line SGD and the bit line BL and the potential difference between the select gate line SGS and the source line SL.

The driver circuit 160 supplies the erase pulse VERA of FIG. 11 to the memory cell MC coupled to the selected word line WL-S corresponding to the selected layer LY.

As described above, voltages VBL2 and VSL2 having positive voltage values are applied to the bit line BL and source line SL, respectively. In this state, the driver circuit 160 applies the selected word line voltage VWLERA having the voltage VSS of 0V to the select word line WL-S corresponding to the selected layer LY.

In the present embodiment, GIDL occurs at the channel edges of the select transistors ST1 and ST2 according to the potential difference between the bit line BL and the gate of the select transistor ST1 and the potential difference between the source line SL and the select transistor ST2.

The holes attributable to the GIDL move from the vicinity of the select transistors ST1 and ST2 to the selected cell MC-S via the channel region of the non-selected cell MC-U. Thus, the potential of the channel region of the selected cell MC-S becomes a positive potential.

As a result, the potential of the channel region (memory pillar 60) of the selected cell MC-S becomes higher than the potential of the gate of the selected cell MC-S, due to the holes.

Therefore, an erase pulse VERA of negative polarity is applied to each of selected cells MC-S coupled to the selected word line WL-S. For example, the voltage value of the erase pulse VERA is approximately-5V.

As described above, the driver circuit 160 controls the pulse width (voltage supply period) of the erase pulse VERA by controlling the supply periods of the bit line voltage VBL2, the source line voltage VSL2, and the selection word line voltage VWLERA.

Thus, the selected cell MC-S in the selected layer LY is set to the erased state.

Thereafter, under the control of the sequencer 190, the driver circuit 160 stops application of the erase pulse VERA by setting the bit line voltage VBL2 and the source line voltage VSL2 to the voltage VSS at time t13. Thereafter, the application of the non-selection voltage VUSEL2 is stopped at time t14.

In the manner described above, the erase sequence is completed in the memory device 1 of the present embodiment.

It should be noted that in the erase sequence of the present embodiment, a potential difference of −2.5V (negative polarity voltage) is applied between the gate and channel of the non-selected cell MC-U. Therefore, erase disturb may occur in the non-selected cell MC-U. However, the absolute value of the negative voltage applied to the non-selected cell MC-U is smaller than the absolute value of the erase pulse VERA.

### <Write Sequence>

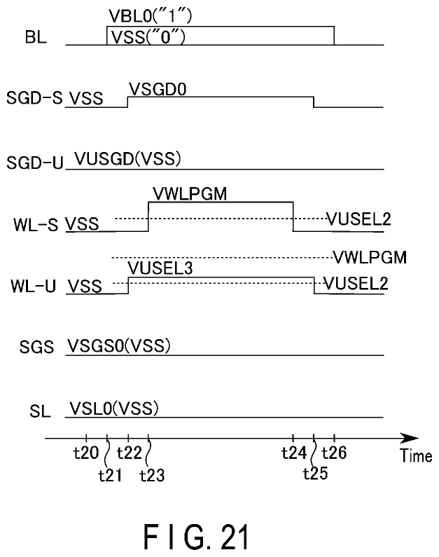

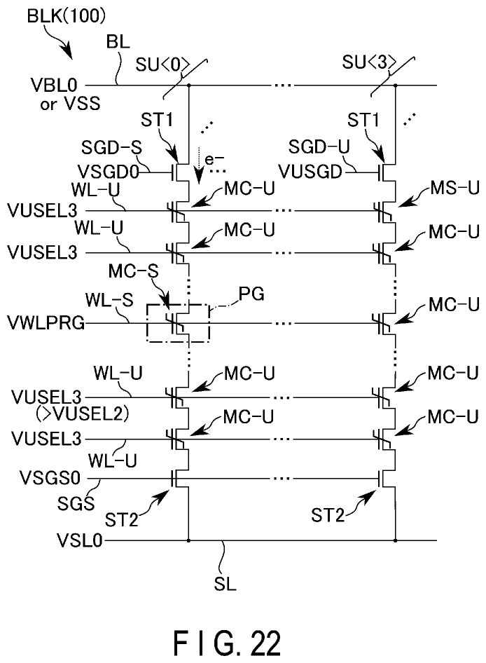

The write sequence of the memory device 1 of the present embodiment will be described with reference to FIG. 21 and FIG. 22.

FIG. 21 is a timing chart showing a change in the potential of each interconnect of the selected block BLK in the write sequence of the memory device 1 of the present embodiment. FIG. 22 is a schematic diagram for illustrating the write sequence of the memory device 1 of the present embodiment. Similar to the embodiment described above, the memory device 1 of the present embodiment executes a write sequence in units of pages.

During the write sequence, the driver circuit 160 supplies various voltages to the plurality of interconnects WL, SGD, SGS, BL, and SL of the memory cell array 100 under the control of the sequencer 190.

As shown in FIG. 21 and FIG. 22, the driver circuit 160 applies a bit line voltage VBL0 having a voltage value corresponding to write data to the plurality of bit lines BL. The driver circuit 160 applies a source line voltage VSL0 of voltage VSS to the source line SL. It should be noted that in the write sequence, a voltage VSL0 having a positive voltage value may be applied to the source line SL.

The driver circuit 160 applies a voltage VSGD0 having a positive voltage value to the selected select gate line SGD-S. The voltage VSGD0 is approximately +2.5V. The select transistor ST1 coupled to the selected select gate line SGD-S is turned on or off depending upon the voltage of the bit line BL.

The driver circuit 160 applies a voltage VUSGD to the non-selected select gate lines SGD-U. The voltage VUSGD is, for example, a voltage VSS of 0V. Thus, the select transistors ST1 coupled to the non-selected select gate lines SGD-U are turned off. Each of the plurality of memory cell strings (non-selected strings) MS of the non-selected string unit SU-U is electrically isolated from the bit line BL by the select transistors ST1 in the off state.

The driver circuit 160 applies a voltage VSGS0 of 0V or a positive value to the select gate line SGS of the selected block BLK. For example, the select transistor ST2 is turned off. Thus, the memory cell string (selected string) MS of the selected string unit SU-S is electrically isolated from the source line SL.

The non-selected strings MS are electrically isolated from the source line SL and the bit line BL. As a result, the memory pillars 60 of the non-selected string MS are set in the electrically floating state.

The driver circuit 160 applies a write pass voltage (non-selection voltage) VUSEL3 to the plurality of non-selected word lines WL-U. In the present embodiment, the write pass voltage VUSEL3 is higher than the non-selection voltage VUSEL2 during the erase sequence. The write pass voltage VUSEL3 is lower than a selection word line voltage VWLPGM. For example, the write pass voltage VUSEL3 is a voltage of approximately +3V.

The driver circuit 160 applies a selection word line voltage VWLPGM having a positive voltage value to the selected word line WL-S. Thus, a write pulse VWR having positive polarity (positive voltage value Vb) is applied to each of the selected cells MC-S to be programmed.

By the supply of the write pulse VWR, the threshold voltages of the selected cells MC-S can be set to a voltage value in accordance with the write data.

In the non-selected string MS, the potential of the floating memory pillar 60 increases in accordance with the voltage applied to the selected word line WL-S and the voltage applied to the non-selected word line WL-U. For example, the potential of the floating memory pillar 60 of the non-selected string MS-U is approximately +3V.

After the supply of the write pulse VWR, a verify operation is performed for the selected cells MC-S. Based on the result of the verify operation, it is determined whether the write pulse VWR should be applied or whether the write sequence should be ended.

With the operations described above, the write sequence is completed.

### SUMMARY

In the memory device 1 of the present embodiment, erase disturb may occur in non-selected cells MC-U in the erase sequence of FIG. 19 and FIG. 20.

When the write sequence shown in FIG. 21 and FIG. 22 is executed, a positive polarity voltage caused by the non-selection voltage VUSEL3 is applied between the gate and the channel region of each non-selected cell MC-U. Thus, the value of the threshold voltage of each non-selected cell MC-U is slightly shifted to a value corresponding to the programmed state.

As a result, the threshold voltage of the non-selected cell MC-U in which erase disturb has occurred is shifted to a voltage value corresponding to the programmed state by application of the non-selection voltage VUSEL3.

Therefore, when the erase sequence of FIG. 19 and FIG. 20 is executed, the influence of erase disturb that occurs in memory cells (e.g., non-selected cells) during the erase sequence can be canceled by the shift of the value of the threshold voltage of the memory cells (non-selected cells) toward the programmed state when the write sequence of FIG. 21 and FIG. 22 is executed.

Accordingly, the memory device of the present embodiment can improve reliability.

### (3) Modifications

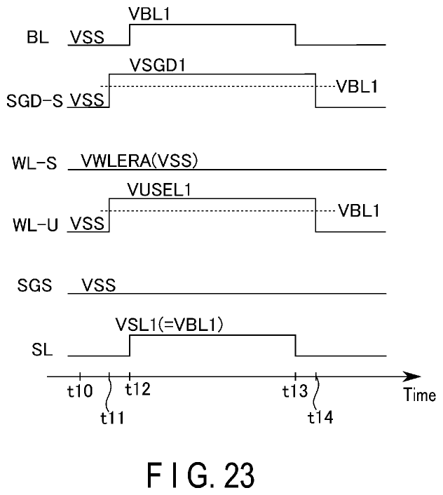

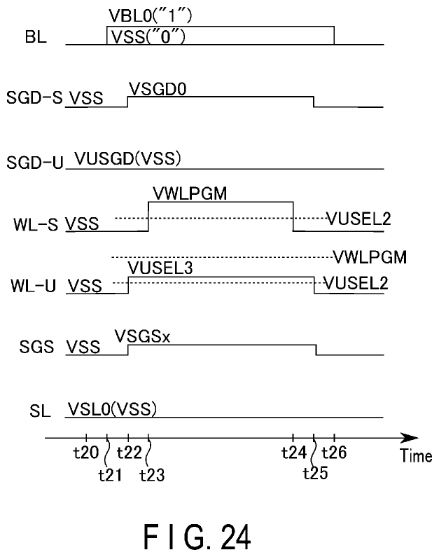

Modifications of the memory devices of the embodiments will be described with reference to FIG. 23 and FIG. 24.

FIG. 23 is a diagram for illustrating a modification of the memory device 1 of the first embodiment. FIG. 23 shows a change in the potential state of each interconnect of the memory cell array 100 in the erase sequence of the modification of the memory device 1 of the first embodiment.

As shown in FIG. 23, a voltage VSS of 0V may be applied to the select gate line SGS in the erase sequence. The select transistor ST2 is turned off. In this case, the source line voltage VSL may be 0V.

It should be noted that a positive voltage VSGD1 may be applied to the select gate line SGS, and a voltage VSS of 0V may be applied to the plurality of select gate lines SGD. In this case, the bit line voltage VBL may be 0V.

Even if the source-side select transistor ST2 (or the drain-side select transistor ST1) of the memory cell string is in the off state, the memory device 1 of the modification shown in FIG. 23 has the advantages described in connection with the first embodiment.

FIG. 24 is a diagram for illustrating a modification of the memory device 1 of the second embodiment. FIG. 24 shows a change in the potential state of each interconnect of the memory cell array changes in the write sequence of the modification of the memory device 1 of the second embodiment.

As shown in FIG. 24, in the write sequence, a voltage VSGSx having a positive voltage value may be applied to the select gate line SGS. A voltage VSS of 0V is applied to the source line SL. The select transistor ST2 operates depending upon the potential difference between the select gate line SGS and the source line SL. For example, the select transistor ST2 coupled to the select gate line SGS is turned on.

Even when the positive voltage VSGSx is applied to the select gate line SGS during the write sequence, the memory device 1 of the modification shown in FIG. 24 has the advantages described in connection with the second embodiment.

It should be noted that in the write sequence of the memory device 1 of the first embodiment, a voltage SGSx may be applied to the select gate line SGS.

As described above, the memory device 1 of the modification can improve the reliability of the memory device.

### (4) Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a first string including a first select transistor, a second select transistor, and a plurality of first memory cells coupled in series between the first select transistor and the second select transistor, the plurality of first memory cells each including a first ferroelectric transistor;
a second string including a third select transistor, a fourth select transistor, and a plurality of second memory cells coupled in series between the third select transistor and the fourth select transistor, the plurality of second memory cells each including a second ferroelectric transistor;
a first select gate line coupled to a gate of the first select transistor;
a second select gate line coupled to a gate of the third select transistor;
a plurality of word lines coupled to gates of the plurality of first memory cells and to gates of the plurality of second memory cells;
a bit line coupled to one end of the first select transistor and one end of the third select transistor;
a source line coupled to one end of the second select transistor and one end of the fourth select transistor; and
a circuit that controls an erase sequence,
wherein
in the erase sequence, the circuit is configured to:
apply a first voltage having a positive voltage value to the bit line;
apply a second voltage having a positive voltage value higher than the first voltage to each of the first select gate line and the second select gate line;
apply a third voltage having a positive voltage value higher than the first voltage to a plurality of first non-selected word lines among the plurality of word lines; and
apply a fourth voltage lower than the first voltage to a first selected word line among the plurality of word lines.

2. The memory device according to claim 1, wherein
in the erase sequence, an erase pulse is supplied to the first and second memory cells coupled to the first selected word line; and
the erase pulse has a negative polarity based on a potential difference between the first voltage and the fourth voltage.

3. The memory device according to claim 1, wherein
a potential of the gates of the first and second memory cells coupled to the first selected word line is lower than a potential of channel edges of the first and second memory cells coupled to the first selected word line.

4. The memory device according to claim 1, wherein
in the erase sequence,
a potential of the gate of the first select transistor is higher than a potential of the one end of the first select transistor, and
a potential of the gate of the third select transistor is higher than a potential of the one end of the third select transistor.

5. The memory device according to claim 1, wherein
in the erase sequence, the first and third select transistors are turned on.

6. The memory device according to claim 1, wherein
in the erase sequence,
potentials of the gates of the plurality of first and second memory cells coupled to the plurality of first non-selected word lines are higher than potentials at channel edges of the plurality of first and second memory cells coupled to the plurality of first non-selected word lines.

7. The memory device according to claim 1, wherein
in the erase sequence, the plurality of first and second memory cells coupled to the plurality of first non-selected word lines are turned on.

8. The memory device according to claim 1, wherein
the third voltage is equal to the second voltage.

9. The memory device according to claim 1, wherein
the fourth voltage is a ground voltage.

10. The memory device according to claim 1, further comprising a third select gate line coupled to gates of the second and fourth select transistors,
wherein
in the erase sequence, the circuit is configured to:
apply the first voltage to the source line; and
apply the second voltage to the third select gate line.

11. The memory device according to claim 1, wherein
the circuit controls a write sequence,
in the write sequence, the circuit is configured to:
apply a fifth voltage having a voltage value corresponding to write data to the bit line;
apply a sixth voltage having a positive voltage value to the first select gate line;
apply a seventh voltage lower than the sixth voltage to the second select gate line;
apply an eighth voltage having a positive voltage value to a plurality of second non-selected word lines among the plurality of word lines; and
apply a ninth voltage having a positive voltage value higher than the eighth voltage to a second selected word line among the plurality of word lines.

12. The memory device according to claim 11, wherein
the sixth voltage is lower than the second voltage, and
the eighth voltage is lower than the third voltage.

13. The memory device according to claim 1, wherein
each of the first and second ferroelectric transistors includes hafnium oxide.

14. A memory device comprising:
a first string including a first select transistor, a second select transistor, and a plurality of first memory cells coupled in series between the first select transistor and the second select transistor, the plurality of first memory cells each including a first ferroelectric transistor;
a second string including a third select transistor, a fourth select transistor, and a plurality of second memory cells coupled in series between the third select transistor and the fourth select transistor, the plurality of second memory cells each including a second ferroelectric transistor;
a first select gate line coupled to a gate of the first select transistor;
a second select gate line coupled to a gate of the third select transistor;
a plurality of word lines coupled to gates of the plurality of first memory cells and to gates of the plurality of second memory cells;
a bit line coupled to one end of the first select transistor and one end of the third select transistor;
a source line coupled to one end of the second select transistor and one end of the fourth select transistor; and
a circuit that controls an erase sequence and a write sequence,
wherein
in the erase sequence, the circuit is configured to:
apply a first voltage having a positive voltage value to the bit line;
apply a second voltage lower than the first voltage to the first and second select gate lines;
apply a third voltage lower than the first voltage and higher than the second voltage to a plurality of first non-selected word lines among the plurality of word lines; and
apply a fourth voltage lower than the third voltage to a first selected word line among the plurality of word lines,
in the write sequence, the circuit is configured to:
apply a fifth voltage having a voltage value corresponding to write data to the bit line;
apply a sixth voltage having a positive voltage value to the first select gate line;
apply a seventh voltage lower than the sixth voltage to the second select gate line;
apply an eighth voltage having a positive voltage value higher than the third voltage to a plurality of second non-selected word lines among the plurality of word lines; and
apply a ninth voltage having a positive voltage value higher than the eighth voltage to a second selected word line among the plurality of word lines.

15. The memory device according to claim 14, wherein
in the erase sequence, an erase pulse is supplied to the first and second memory cells coupled to the first selected word line, and
the erase pulse has a negative polarity based on a potential difference between the first voltage and the fourth voltage,
in the write sequence, a write pulse is supplied to the first memory cell coupled to the second selected word line, and
the write pulse has a positive polarity based on a potential difference between the fifth voltage and the ninth voltage.

16. The memory device according to claim 14, wherein
in the erase sequence,
a potential of the gate of the first select transistor is lower than a potential of the one end of the first select transistor, and
a potential of a gate of the third select transistor is lower than a potential of the one end of the third select transistor.

17. The memory device according to claim 14, wherein
the second and fourth voltages are ground voltages.

18. The memory device according to claim 14, further comprising a third select gate line coupled to gates of the second and fourth select transistors,
wherein
in the erase sequence, the circuit is configured to:
apply the first voltage to the source line; and
apply the second voltage to the third select gate line,
in the write sequence, the circuit is configured to:
apply a tenth voltage to the source line; and
apply the seventh voltage to the third select gate line.

19. The memory device according to claim 14, wherein
each of the first and second ferroelectric transistors includes hafnium oxide.
